(19) United States
(12) Patent Application Publication
(10) Pub. No.: US 2024/0104266 A1
(43) Pub. Date: Mar. 28, 2024

(54) OCCUPANCY MODEL SELECTION APPARATUS, OCCUPANCY MODEL SELECTION METHOD, AND NON-TRANSITORY COMPUTER READABLE MEDIUM

(71) Applicant: MITSUBISHI ELECTRIC CORPORATION, Tokyo (JP)

(72) Inventors: Risa MURAKAMI, Tokyo (JP); Shinichiro OTANI, Tokyo (JP)

(73) Assignee: MITSUBISHI ELECTRIC CORPORATION, Tokyo (JP)

(21) Appl. No.: 18/535,042

(22) Filed: Dec. 11, 2023

Related U.S. Application Data
(63) Continuation of application No. PCT/JP2021/029417, filed on Aug. 6, 2021.

(51) Int. Cl. G06F 30/20; G06F 11/30

(52) U.S. Cl. CPC G06F 30/20; G06F 11/3062

(57) ABSTRACT

An occupancy model selection apparatus (100) includes an occupancy model selection unit (103). The occupancy model selection unit (103) evaluates each of a plurality of occupancy models which predict occupancy situation in a simulation target area during a simulation period, based on a power consumption value corresponding to each of the plurality of occupancy models and on a past input condition; and based on a result of evaluation of each of the plurality of occupancy models, selects an occupancy model that generates a simulation result relatively close to an actual power consumption value in the simulation period corresponding to the past input condition in the simulation target area.

### CROSS REFERENCE TO RELATED APPLICATIONS

This application is a Continuation of PCT International Application No. PCT/JP2021/029417, filed on Aug. 6, 2021, which is hereby expressly incorporated by reference into the present application.

### TECHNICAL FIELD

The present disclosure relates to an occupancy model selection apparatus, an occupancy model selection method, and an occupancy model selection program.

### BACKGROUND ART

In recent years, efficient energy management for the purpose of energy saving has been needed due to growing interest in prevention of global warming, reduction of environmental burden, or the like. For efficient energy management, accurate simulations of power consumption are required. In a simulation of power consumption in a building, the number of occupants that are assumed to be present in a simulation target area during a simulation period can be modeled into an occupancy model in order to calculate heat load in the simulation target area that will be processed by a facility disposed in the building, and the occupancy model can be used as input information.

Patent Literature 1 discloses a method of defining an occupancy model for use in a simulation based on the number of occupants obtained during execution of a simulation.

### CITATION LIST

### Patent Literature

Patent Literature 1: JP 2012-194700 A1

### SUMMARY OF INVENTION

### Technical Problem

The method disclosed by Patent Literature 1 defines an occupancy model at the time of performing a simulation by making a correction to modify an original occupancy model in accordance with the number of occupants who are present during the simulation to reconstruct the occupancy model. Accordingly, the method has a drawback of being unable to smoothly perform a power consumption simulation because it requires an occupancy model to be reconstructed when a power consumption simulation is performed.

An object of the present disclosure is to smoothly execute a simulation of power consumption without reconstructing an occupancy model when a simulation of power consumption is performed.

### Solution to Problem

An occupancy model selection apparatus according to the present disclosure includes:
an occupancy model selection unit to evaluate each of a plurality of occupancy models which predict occupancy situation in a simulation target area during a simulation period, the evaluating based on a power consumption value corresponding to each of the plurality of occupancy models and on a past input condition, the past input condition being a condition that affects a power consumption value in an area equivalent to the simulation target area during a period equivalent to the simulation period and that was used in a past simulation of the power consumption value in an area equivalent to the simulation target area during a period equivalent to the simulation period; and based on a result of evaluation of each of the plurality of occupancy models, further to select as a selected occupancy model from among the plurality of occupancy models, an occupancy model that generates a simulation result relatively close to an actual power consumption value in the simulation period corresponding to the past input condition in the area equivalent to the simulation target area, in a simulation of power consumption in an area equivalent to the simulation target area during a period equivalent to the simulation period.

### Advantageous Effects of Invention

According to the present disclosure, the occupancy model selection unit evaluates each of multiple occupancy models and selects an appropriate occupancy model from the multiple occupancy models based on the evaluation of each of the multiple occupancy models. Then, a power consumption simulation can be performed using the occupancy model selected by the occupancy model selection unit. Thus, according to the present disclosure, a simulation of power consumption can be smoothly executed without reconstructing an occupancy model when a simulation of power consumption is performed.

### BRIEF DESCRIPTION OF DRAWINGS

FIG. 1 shows an exemplary hardware configuration of an occupancy model selection apparatus 100 according to Embodiment 1.

FIG. 2 shows an exemplary functional configuration of the occupancy model selection apparatus 100 according to Embodiment 1.

FIG. 3 is a flowchart illustrating operations of the occupancy model selection apparatus 100 according to Embodiment 1.

FIG. 4 shows an exemplary hardware configuration of the occupancy model selection apparatus 100 according to a modification of Embodiment 1.

FIG. 5 shows an exemplary functional configuration of the occupancy model selection apparatus 100 according to Embodiment 2.

FIG. 6 is a flowchart illustrating operations of the occupancy model selection apparatus 100 according to Embodiment 2.

FIG. 7 shows an exemplary functional configuration of the occupancy model selection apparatus 100 according to Embodiment 3.

FIG. 8 is a flowchart illustrating operations of the occupancy model selection apparatus 100 according to Embodiment 3.

FIG. 9 shows an exemplary functional configuration of the occupancy model selection apparatus 100 according to Embodiment 4.

FIG. 10 is a flowchart illustrating operations of the occupancy model selection apparatus 100 according to Embodiment 4.

FIG. 11 shows an exemplary functional configuration of the occupancy model selection apparatus 100 according to Embodiment 5.

FIG. 12 is a flowchart illustrating operations of the occupancy model selection apparatus 100 according to Embodiment 5.

FIG. 13 shows an exemplary functional configuration of the occupancy model selection apparatus 100 according to Embodiment 6.

FIG. 14 is a flowchart illustrating operations of the occupancy model selection apparatus 100 according to Embodiment 6.

FIG. 15 shows an exemplary functional configuration of the occupancy model selection apparatus 100 according to Embodiment 7.

FIG. 16 is a flowchart illustrating operations of the occupancy model selection apparatus 100 according to Embodiment 7.

FIG. 17 is a diagram describing occupancy models according to Embodiment 7, where (a) is an occupancy history and (b) is an occupancy model based on occupancy rates.

FIG. 18 shows an exemplary functional configuration of the occupancy model selection apparatus 100 according to Embodiment 8.

FIG. 19 is a flowchart illustrating operations of the occupancy model selection apparatus 100 according to Embodiment 8.

FIG. 20 shows an exemplary functional configuration of the occupancy model selection apparatus 100 according to Embodiment 9.

FIG. 21 is a flowchart illustrating operations of the occupancy model selection apparatus 100 according to Embodiment 9.

FIG. 22 shows an exemplary functional configuration of the occupancy model selection apparatus 100 according to Embodiment 10.

FIG. 23 is a flowchart illustrating operations of the occupancy model selection apparatus 100 according to Embodiment 10.

FIG. 24 shows an exemplary functional configuration of the occupancy model selection apparatus 100 according to Embodiment 11.

FIG. 25 is a flowchart illustrating operations of the occupancy model selection apparatus 100 according to Embodiment 11.

FIG. 26 shows an exemplary functional configuration of the occupancy model selection apparatus 100 according to Embodiment 12.

FIG. 27 is a flowchart illustrating operations of the occupancy model selection apparatus 100 according to Embodiment 12.

### DESCRIPTION OF EMBODIMENTS

In the description of embodiments and the drawings, the same elements and the corresponding elements are given the same reference characters. Description on elements with the same reference characters are omitted or simplified as appropriate. Arrows in the drawings primarily indicate flow of data or flow of processing. Also, a “unit” can be read as a “circuit”, “step”, “procedure”, “process”, or “circuitry” as appropriate.

### Embodiment 1

The present embodiment is described in detail below with reference to drawings.

***Description of Configuration***

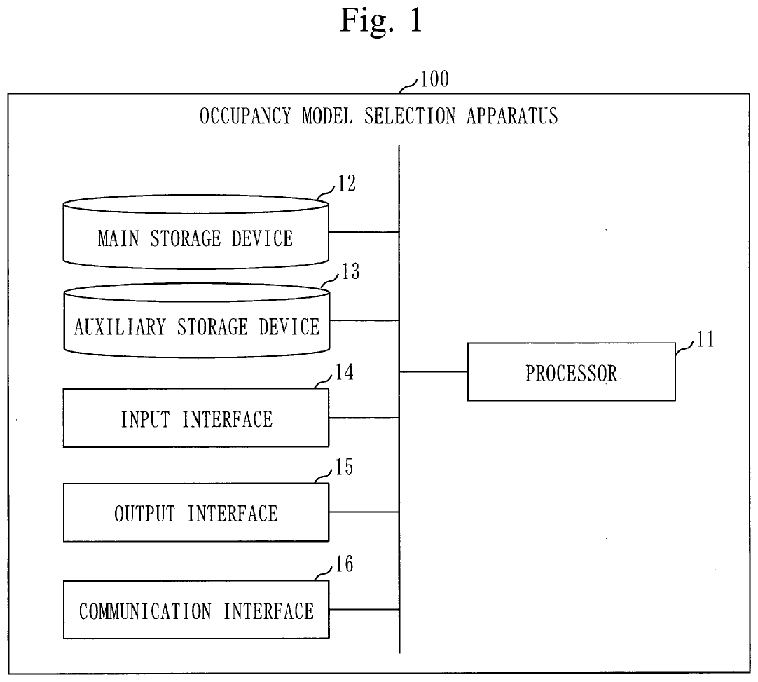

FIG. 1 shows an exemplary hardware configuration of an occupancy model selection apparatus 100 according to the present embodiment.

As shown in this drawing, the occupancy model selection apparatus 100 is a computer including pieces of hardware such as a processor 11, a main storage device 12, an auxiliary storage device 13, an input interface 14, an output interface 15, and a communication interface 16. These pieces of hardware are appropriately connected via signal lines. The occupancy model selection apparatus 100 may also be formed of multiple computers.

The processor 11 is an IC (Integrated Circuit) that performs arithmetic processing and controls the hardware included with the computer. The processor 11 can be a CPU (Central Processing Unit), a DSP (Digital Signal Processor), or a GPU (Graphics Processing Unit) as specific examples.

The occupancy model selection apparatus 100 may also include multiple processors to replace the processor 11. The multiple processors share the roles of the processor 11.

The main storage device 12 is typically a volatile storage device. The main storage device 12 is also called a main storage or a main memory. The main storage device 12 is a RAM (Random Access Memory) as a specific example. Data stored in the main storage device 12 is saved in the auxiliary storage device 13 as needed.

The auxiliary storage device 13 is typically a non-volatile storage device. The auxiliary storage device 13 is a ROM (Read Only Memory), an HDD (Hard Disk Drive), or a flash memory as specific examples. Data stored in the auxiliary storage device 13 is loaded into the main storage device 12 as needed.

The main storage device 12 and the auxiliary storage device 13 may also be integrally configured.

The input interface 14 is a port to which input devices are connected. The input interface 14 is a USB (Universal Serial Bus) terminal as a specific example. The input devices are a keyboard and a mouse as specific examples.

The output interface 15 is a port to which output devices are connected. The output interface 15 is a USB terminal as a specific example. The output device is a display as a specific example.

The communication interface 16 is a receiver and transmitter. The communication interface 16 is a communication chip or a NIC (Network Interface Card) as specific examples.

The components of the occupancy model selection apparatus 100 may use the input interface 14, the output interface 15, and the communication interface 16 as appropriate when communicating with other devices or the like.

The auxiliary storage device 13 stores an occupancy model selection program. The occupancy model selection program is a program that causes a computer to implement the functions of the components provided in the occupancy model selection apparatus 100. The occupancy model selection program is loaded to the main storage device 12 and executed by the processor 11. The functions of the components included in the occupancy model selection apparatus 100 are implemented by software.

Data for use in execution of the occupancy model selection program and data resulting from execution of the occupancy model selection program are stored in a storage device as necessary. The components of the occupancy model selection apparatus 100 utilize the storage device as necessary. The storage device is formed of at least one of the main storage device 12, the auxiliary storage device 13, a register in the processor 11, and a cache memory in the processor 11. Data and information sometimes have equivalent meaning. The storage device may be independent of the computer.

The functions of the main storage device 12 and the auxiliary storage device 13 may also be implemented by other storage device.

The occupancy model selection program may be recorded on a computer-readable, non-volatile recording medium. The non-volatile recording medium can be an optical disk or a flash memory as specific examples. The occupancy model selection program may be provided as a program product.

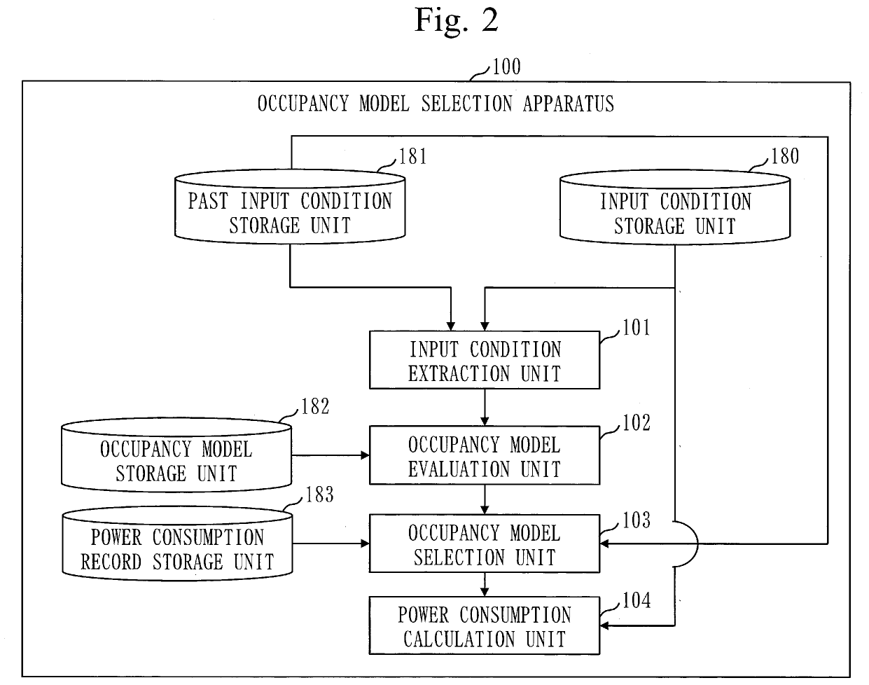

FIG. 2 shows an exemplary functional configuration of the occupancy model selection apparatus 100 according to Embodiment 1.

The occupancy model selection apparatus 100 is configured of an input condition storage unit 180, a past input condition storage unit 181, an input condition extraction unit 101, an occupancy model storage unit 182, an occupancy model evaluation unit 102, a power consumption record storage unit 183, an occupancy model selection unit 103, and a power consumption calculation unit 104, as shown in FIG. 2.

Major simulations related to the present disclosure include simulation for occupancy model selection, which selects an optimal occupancy model based on past records, and simulation after occupancy model selection, which simulates a future power consumption value after an optimal occupancy model is selected.

(Input Condition Storage Unit 180)

The input condition storage unit 180 accumulates simulation target information which is input in a simulation after occupancy model selection, and outputs accumulated simulation target information. The simulation target information represents an input condition for a simulation and indicates each of a building model, a weather model, and a facility operation model as specific examples. An input condition is a condition that affects the power consumption value in the simulation target area during the simulation period.

The building model is a model consisting of numerical values that indicate the structure of the simulation target area. The simulation target area is the target area of a power consumption simulation and can be the interior of a building as a specific example.

The weather model is a model consisting of numerical values that indicate the weather that is assumed in the simulation period. The simulation period is the target period of a power consumption simulation.

The facility operation model is a model consisting of numerical values that indicate the schedule according to which a facility in the simulation target area operates and which is assumed in the simulation period.

(Past Input Condition Storage Unit 181)

The past input condition storage unit 181 accumulates past simulation target information, which is information to be input to a simulation for occupancy model selection and corresponds to the simulation target area, and outputs accumulated past simulation target information. The past simulation target information represents past input conditions and indicates each of a building model, a weather model, an occupancy model, and a facility operation model as specific examples. A past input condition is a condition that affects the power consumption value in an area equivalent to the simulation target area during a period equivalent to the simulation period and that was used in a past simulation of the power consumption value in an area equivalent to the simulation target area during a period equivalent to the simulation period. An area equivalent to the simulation target area may be the simulation target area itself or an area similar to the simulation target area. A period equivalent to the simulation period may be a period of the same length as the simulation period.

The occupancy model is a model that predicts an occupancy situation in the simulation target area during the simulation period and that consists of parameters indicating the occupancy situation in the simulation target area.

(Input Condition Extraction Unit 101)

First, the input condition extraction unit 101 calculates the length of the simulation period for a simulation after occupancy model selection using the simulation target information output from the input condition storage unit 180. Next, the input condition extraction unit 101 retrieves past simulation target information corresponding to a simulation period of the same length as the calculated length of the simulation period from the past input condition storage unit 181, and outputs the retrieved past simulation target information. The output past simulation target information will be used in a simulation for occupancy model selection.

(Occupancy Model Storage Unit 182)

The occupancy model storage unit 182 accumulates multiple occupancy models and outputs accumulated occupancy models. Each of the multiple occupancy models may be predefined in each of multiple methods. The number of occupancy models accumulated in the occupancy model storage unit 182 may also be one.

(Occupancy Model Evaluation Unit 102)

The occupancy model evaluation unit 102 determines a power consumption value corresponding to each of the multiple occupancy models based on each of the multiple occupancy models and the past input condition. As a specific example, for determining the power consumption value corresponding to each of multiple occupancy models, the occupancy model evaluation unit 102 obtains multiple simulation results corresponding to the multiple occupancy models respectively, by simulating the power consumption value in an area equivalent to the simulation target area during a period equivalent to the simulation period using each of the multiple occupancy models and the past input condition. Specifically, the occupancy model evaluation unit 102 calculates a power consumption value corresponding to each occupancy model during a period equivalent to the simulation period by executing a simulation for occupancy model selection using the past simulation target information output from the input condition extraction unit 101 and each of the occupancy models output from the occupancy model storage unit 182, and outputs information showing the calculated power consumption value corresponding to each occupancy model.

(Power Consumption Record Storage Unit 183)

The power consumption record storage unit 183 accumulates information showing actual power consumption values of a facility in the simulation target area and outputs accumulated information showing actual power consumption values.

(Occupancy Model Selection Unit 103)

The occupancy model selection unit 103 evaluates each of the multiple occupancy models based on the power consumption value corresponding to each of the multiple occupancy models and the past input condition, and based on the result of evaluation of each of the multiple occupancy models, selects as a selected occupancy model from among the multiple occupancy models, an occupancy model that generates a simulation result relatively close to the actual power consumption value in the simulation period corresponding to the past input condition in an area equivalent to the simulation target area, in a simulation of the power consumption in the area equivalent to the simulation target area during the period equivalent to the simulation period. That is, the occupancy model selection unit 103 selects an occupancy model corresponding to a simulation result that is relatively close to the actual power consumption value among multiple simulation results as the selected occupancy model.

As a specific example, the occupancy model selection unit 103 retrieves, from the power consumption record storage unit 183, the actual power consumption value of the facility in the period equivalent to the simulation period that corresponds to the past simulation target information output from the past input condition storage unit 181. Then, the occupancy model selection unit 103 compares the retrieved power consumption value with the power consumption value corresponding to each occupancy model output from the occupancy model evaluation unit 102, and among the power consumption values corresponding to the respective occupancy models, outputs the occupancy model that corresponds to the power consumption value with the smallest error with respect to the retrieved power consumption value.

(Power Consumption Calculation Unit 104)

The power consumption calculation unit 104 calculates the power consumption value in the simulation target area during the simulation period by executing a simulation after occupancy model selection using the simulation target information output from the input condition storage unit 180 and the occupancy model output from the occupancy model selection unit 103.

***Description of Operation***

An operational procedure of the occupancy model selection apparatus 100 corresponds to an occupancy model selection method. A program for implementing the operation of the occupancy model selection apparatus 100 corresponds to an occupancy model selection program.

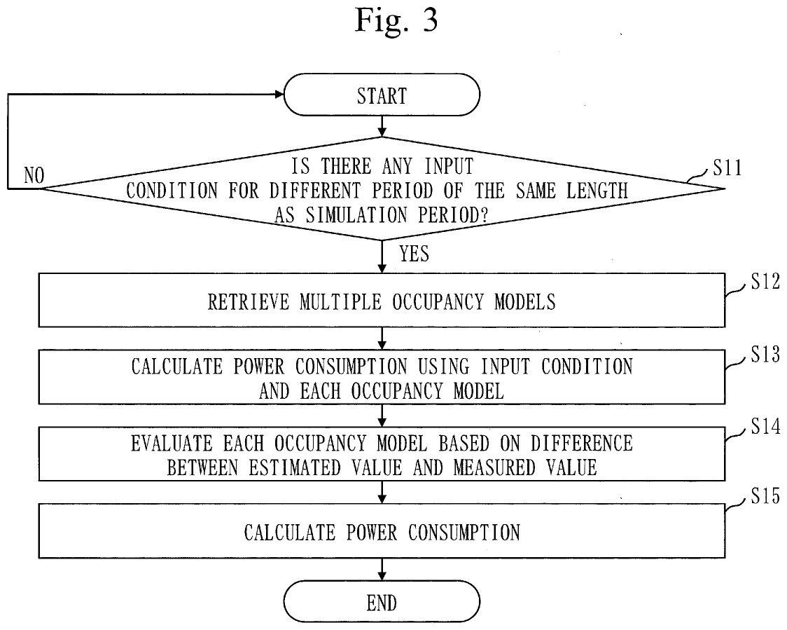

FIG. 3 is a flowchart illustrating an example of the operation of the occupancy model selection apparatus 100 according to Embodiment 1. With reference to this drawing, the operation of the occupancy model selection apparatus 100 is described.

(Step S11)

First, the input condition extraction unit 101 uses simulation target information output from the input condition storage unit 180 to calculate the length of the simulation period corresponding to the simulation target information. Next, the input condition extraction unit 101 retrieves past simulation target information corresponding to a period equivalent to the simulation period of the same length as the calculated length of the simulation period from the past input condition storage unit 181, and outputs the retrieved past simulation target information to the occupancy model evaluation unit 102.

If the past input condition storage unit 181 has accumulated no past simulation target information corresponding to a period equivalent to the simulation period of the same length as the calculated length of the simulation period, the occupancy model selection apparatus 100 repeats the processing for this step.

(Step S12)

The occupancy model evaluation unit 102 retrieves multiple occupancy models accumulated in the occupancy model storage unit 182 from the occupancy model storage unit 182. The occupancy model storage unit 182 may not output all of the occupancy models accumulated therein and the occupancy model evaluation unit 102 may select occupancy models to retrieve from the occupancy model storage unit 182 in accordance with the past simulation target information output by the input condition extraction unit 101 or the like.

(Step S13)

The occupancy model evaluation unit 102 calculates the power consumption value corresponding to each occupancy model by executing a simulation for occupancy model selection using the past simulation target information output from the input condition extraction unit 101 and each of the occupancy models retrieved from the occupancy model storage unit 182, and outputs information showing the calculated power consumption values corresponding to the respective occupancy models to the occupancy model selection unit 103.

(Step S14)

First, the occupancy model selection unit 103 retrieves, from the power consumption record storage unit 183, the actual power consumption value of the facility in the simulation target area in a period equivalent to the simulation period corresponding to the past simulation target information. Next, the occupancy model selection unit 103 compares the retrieved actual power consumption value with the power consumption value corresponding to each occupancy model output from the occupancy model evaluation unit 102, and among the power consumption values corresponding to the respective occupancy models output from the occupancy model evaluation unit 102, outputs the occupancy model that corresponds to the power consumption value with the smallest error with respect to the retrieved power consumption value to the power consumption calculation unit 104.

(Step S15)

The power consumption calculation unit 104 calculates the power consumption value in the simulation target area during the simulation period by executing a simulation after occupancy model selection using the simulation target information output from the input condition storage unit 180 and the occupancy model output from the occupancy model selection unit 103.

***Description of Effects of Embodiment 1***

Through the operations above, the occupancy model selection apparatus 100 according to Embodiment 1 can select an occupancy model that is appropriate in terms of simulation accuracy from multiple defined occupancy models based on past simulation records. Thus, according to the present embodiment, definition of occupancy models is made more efficient by eliminating the necessity to reconstruct an occupancy model when a power consumption simulation is performed and the simulation accuracy of power consumption in a building can be improved.

***Other Configurations***

<Modification 1>

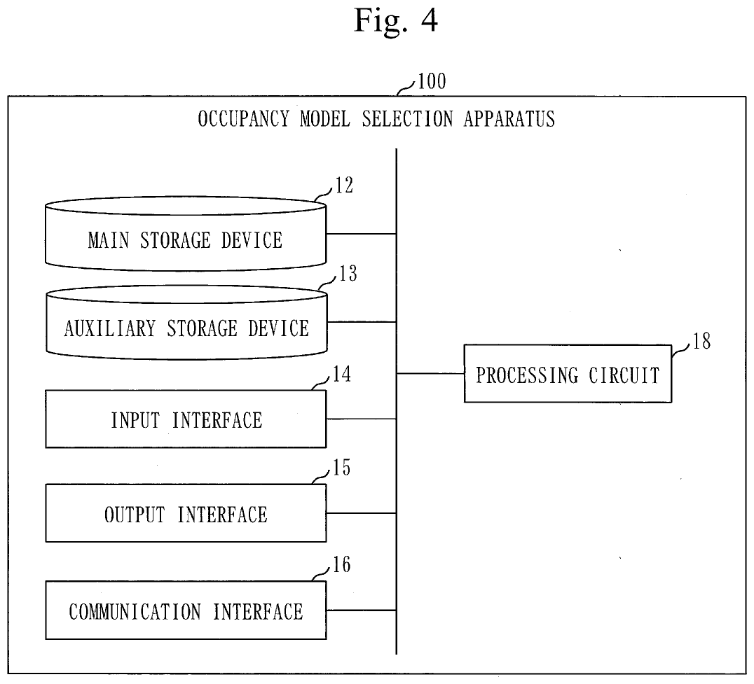

FIG. 4 shows an exemplary hardware configuration of the occupancy model selection apparatus 100 according to this modification.

The occupancy model selection apparatus 100 includes a processing circuit 18 in place of the processor 11, the processor 11 and the main storage device 12, the processor 11 and the auxiliary storage device 13, or the processor 11 and the main storage device 12 and the auxiliary storage device 13.

The processing circuit 18 is hardware that implements at least some of the components included in the occupancy model selection apparatus 100.

The processing circuit 18 may be dedicated hardware or may be a processor that executes programs stored in the main storage device 12.

When the processing circuit 18 is dedicated hardware, the processing circuit 18 can be a single circuit, a composite circuit, a programmed processor, a parallel-programmed processor, an ASIC (Application Specific Integrated Circuit), an FPGA (Field Programmable Gate Array), or a combination thereof, as specific examples.

The occupancy model selection apparatus 100 may include multiple processing circuits to replace the processing circuit 18. The multiple processing circuits share the roles of the processing circuit 18.

In the occupancy model selection apparatus 100, some of the functions may be implemented by dedicated hardware and the remaining functions may be implemented by software or firmware.

The processing circuit 18 is implemented by hardware, software, firmware, or a combination thereof, as specific examples.

The processor 11, the main storage device 12, the auxiliary storage device 13, and the processing circuit 18 are collectively called “processing circuitry”. That is, the functions of the functional components of the occupancy model selection apparatus 100 are implemented by the processing circuitry.

The occupancy model selection apparatuses 100 according to other embodiments may have a similar configuration to this modification.

### Embodiment 2

In the following, differences from the aforementioned embodiment are chiefly described with reference to drawings.

In Embodiment 1, a simulation for occupancy model selection is performed based on the records of past simulations by using past simulation target information, and an occupancy model is selected based on errors associated with the power consumption values indicated by the execution results of simulations.

In Embodiment 2, by contrast, an occupancy model is selected based on errors associated with an occupancy model as one element of past simulation target information.

***Description of Configuration***

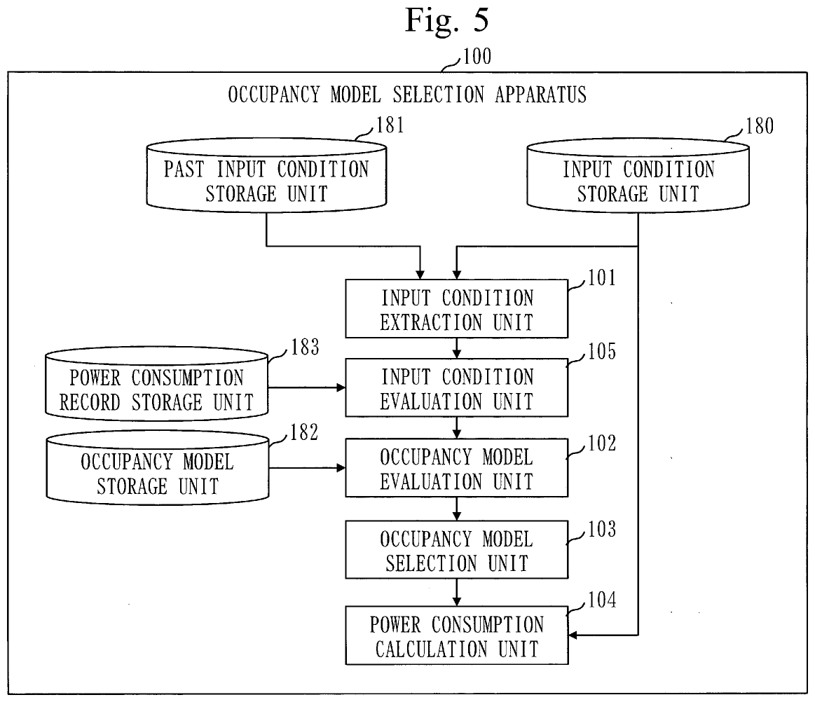

FIG. 5 shows an exemplary functional configuration of the occupancy model selection apparatus 100 according to the present embodiment. As shown in this drawing, the occupancy model selection apparatus 100 is configured of the input condition storage unit 180, the past input condition storage unit 181, the input condition extraction unit 101, the power consumption record storage unit 183, an input condition evaluation unit 105, the occupancy model storage unit 182, the occupancy model selection unit 103, and the power consumption calculation unit 104.

The past input condition storage unit 181 accumulates each past simulation target information that was used when a simulation after occupancy model selection was executed for the simulation target area in the past and also information showing the power consumption value that was calculated in a simulation after occupancy model selection using that past simulation target information as the power consumption values corresponding to that past simulation target information, and outputs information showing the accumulated past simulation target information and accumulated power consumption values that correspond to the past simulation target information. The past input condition storage unit 181 stores each of one or more past input conditions in association with the simulation result of a simulation that uses each of the one or more past input conditions and that is for the power consumption value in an area equivalent to the simulation target area during a period equivalent to the simulation period.

First, the input condition extraction unit 101 uses simulation target information output from the input condition storage unit 180 to calculate the length of the simulation period corresponding to the simulation target information. Next, the input condition extraction unit 101 retrieves at least one pair of past simulation target information that corresponds to a period equivalent to simulation period of the same length as the calculated length of the simulation period and the power consumption value corresponding to that past simulation target information from the past input condition storage unit 181, and outputs information showing the retrieved pair.

(Input Condition Evaluation Unit 105)

The input condition evaluation unit 105 uses each past simulation target information output from the input condition extraction unit 101 to retrieve the simulation period corresponding to each past simulation target information, and also retrieves the power consumption value corresponding to each past simulation target information output from the input condition extraction unit 101. Then, the input condition evaluation unit 105 retrieves the actual power consumption value of the facility in the simulation period from the power consumption record storage unit 183, compares the retrieved actual power consumption value with the power consumption value corresponding to each past simulation target information, and among the power consumption values corresponding to the respective pieces of past simulation target information, outputs the past simulation target information corresponding to the power consumption value with the smallest error with respect to the actual power consumption value. The input condition evaluation unit 105 selects an occupancy model that corresponds to a simulation result relatively close to the actual power consumption value from among the occupancy models indicated by the one or more past input conditions, respectively. This occupancy model is also called a similar-power occupancy model.

The occupancy model evaluation unit 102 retrieves the occupancy model which is indicated by the past simulation target information output from the input condition evaluation unit 105.

The occupancy model selection unit 103 calculates the error between the occupancy model retrieved by the occupancy model evaluation unit 102 and each of the occupancy models output from the occupancy model storage unit 182, compares the errors between the occupancy model retrieved by the occupancy model evaluation unit 102 and the respective ones of the occupancy models output from the occupancy model storage unit 182, and outputs the occupancy model with the smallest error with respect to the occupancy model retrieved by the occupancy model evaluation unit 102 among the occupancy models output from the occupancy model storage unit 182. The occupancy model selection unit 103 selects an occupancy model with a relatively small difference with respect to the similar-power occupancy model as the selected occupancy model. An occupancy model thus selected is considered to be an occupancy model that would generate a simulation result relatively close to the actual power consumption value.

***Description of Operation***

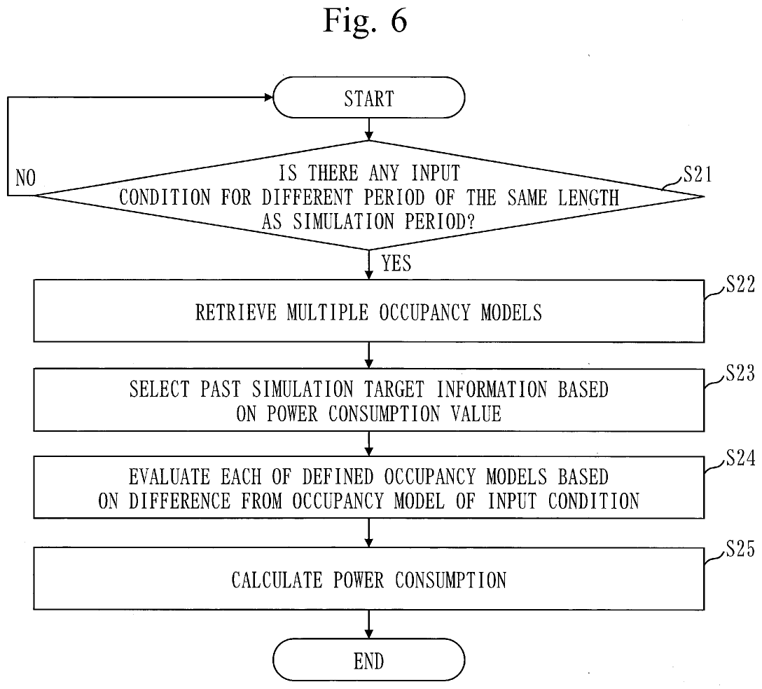

FIG. 6 is a flowchart illustrating an example of the operation of the occupancy model selection apparatus 100 according to Embodiment 2. With reference to this drawing, the operation of the occupancy model selection apparatus 100 is described.

(Step S21)

First, the input condition extraction unit 101 uses simulation target information output from the input condition storage unit 180 to calculate the length of the simulation period corresponding to the simulation target information. Next, the input condition extraction unit 101 retrieves at least one pair of past simulation target information corresponding to a period equivalent to the simulation period of the same length as the calculated length of the simulation period and the power consumption value corresponding to the past simulation target information from the past input condition storage unit 181, and outputs information showing the retrieved pair to the input condition evaluation unit 105.

(Step S22)

This step is the same as step S12.

(Step S23)

The input condition evaluation unit 105 uses each past simulation target information output from the input condition extraction unit 101 to retrieve the period equivalent to the simulation period corresponding to each past simulation target information, and also retrieves the power consumption value corresponding to each past simulation target information output from the input condition extraction unit 101. Then, the input condition evaluation unit 105 retrieves the actual power consumption value of the facility in a period equivalent to the simulation period from the power consumption record storage unit 183, compares the retrieved actual power consumption value with the power consumption value corresponding to each past simulation target information, and among the power consumption values corresponding to the respective pieces of past simulation target information, outputs the past simulation target information corresponding to the power consumption value with the smallest error with respect to the actual power consumption value to the occupancy model evaluation unit 102.

(Step S24)

The occupancy model evaluation unit 102 retrieves the occupancy model which is indicated by the past simulation target information output from the input condition evaluation unit 105, and outputs it to the occupancy model selection unit 103.

The occupancy model selection unit 103 calculates the error between the retrieved occupancy model and each occupancy model output from the occupancy model storage unit 182. Specifically, the occupancy model selection unit 103 calculates a Euclidean distance, determined from [FORMULA 1] below, between an occupancy model x retrieved from the occupancy model evaluation unit 102 and each occupancy model y which is output from the occupancy model storage unit 182, as the error corresponding to the occupancy model y. Here, n is an integer equal to or greater than 1, i is an integer from 1 to n inclusive, xᵢ indicates the number of occupants at time tᵢ for the occupancy model x, and yᵢ indicates the number of occupants at time tᵢ for the occupancy model y. Time tᵢ may also be a variable indicative of a certain hour of day.

\sqrt{(x₁−y₁)²+ . . . +(xᵢ−yᵢ)²+ . . . +(xₙ−yₙ)²} [FORMULA 1]

Then, the occupancy model selection unit 103 compares the calculated errors that respectively correspond to the occupancy models output from the occupancy model storage unit 182 with one another, and outputs the occupancy model with the smallest error with respect to the retrieved occupancy model among the occupancy models output from the occupancy model storage unit 182 to the power consumption calculation unit 104.

(Step S25)

This step is the same as step S15.

***Description of Effects of Embodiment 2***

Through the operations above, the occupancy model selection apparatus 100 according to Embodiment 2 can select the most appropriate occupancy model having high simulation accuracy from the multiple defined occupancy models based on past simulation records. Thus, according to the present embodiment, the simulation accuracy of power consumption can be improved.

### Embodiment 3

In the following, differences from the aforementioned embodiment are chiefly described with reference to drawings.

In Embodiment 1, a single piece of past simulation target information is used to select an occupancy model.

In Embodiment 3, by contrast, multiple pieces of past simulation target information are used to select an occupancy model.

***Description of Configuration***

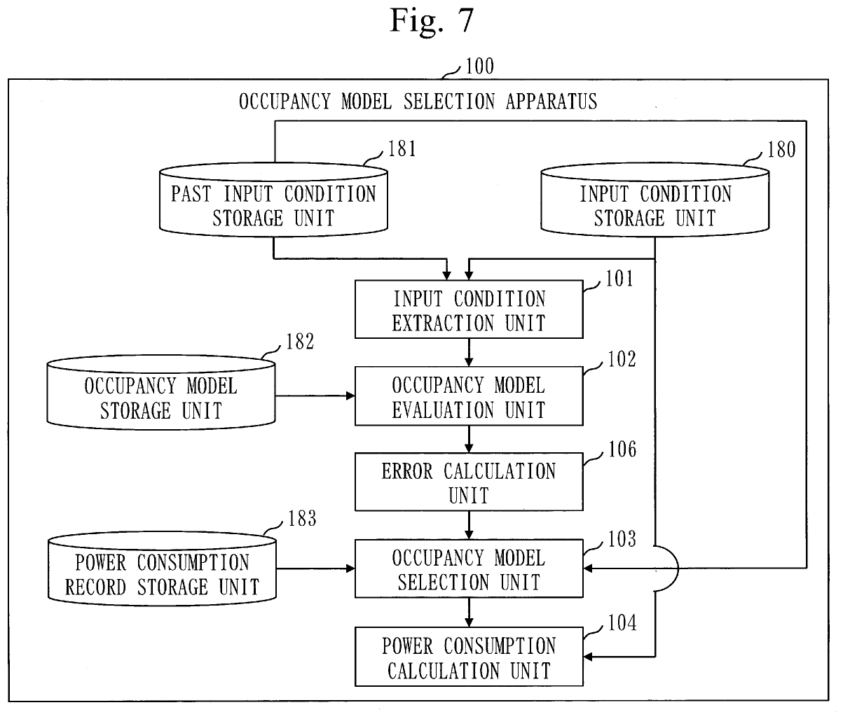

FIG. 7 shows an exemplary functional configuration of the occupancy model selection apparatus 100 according to the present embodiment. The occupancy model selection apparatus 100 is configured of the input condition storage unit 180, the past input condition storage unit 181, the input condition extraction unit 101, the occupancy model storage unit 182, the occupancy model evaluation unit 102, an error calculation unit 106, the power consumption record storage unit 183, the occupancy model selection unit 103, and the power consumption calculation unit 104, as shown in FIG. 7. The error calculation unit 106 is also called an occupancy model selection value calculation unit.

The input condition extraction unit 101 retrieves, from the past input condition storage unit 181, at least two pieces of past simulation target information that correspond to a period equivalent to the simulation period of the same length as the simulation period corresponding to the simulation target information output from the input condition storage unit 180, and outputs the retrieved at least two pieces of past simulation target information.

The occupancy model evaluation unit 102 calculates the power consumption value corresponding to each combination of multiple pieces of past simulation target information and one or more occupancy models by executing a simulation for occupancy model selection for each such combination, as the power consumption value corresponding to each occupancy model for each past simulation target information, and outputs the calculated power consumption values. For evaluating each of the multiple occupancy models, the occupancy model evaluation unit 102 determines the power consumption value corresponding to each combination of the multiple past input conditions and the multiple occupancy models by a simulation.

The occupancy model selection unit 103 selects a selected occupancy model based on errors with respect to the actual power consumption value for the respective ones of the multiple occupancy models.

(Error Calculation Unit 106)

First, for each past simulation target information, the error calculation unit 106 calculates the error of the power consumption value corresponding to each past simulation target information output from the occupancy model evaluation unit 102 by comparing the power consumption value corresponding to each past simulation target information output from the occupancy model evaluation unit 102 with the actual power consumption value of the facility corresponding to that past simulation target information output from the power consumption record storage unit 183. Next, the error calculation unit 106 aggregates and outputs the errors of the power consumption values for each occupancy model. In doing so, the error calculation unit 106 calculates an average of the errors of the power consumption values of each occupancy model and outputs the calculated average of the errors, as a specific example. Here, the average of the errors of power consumption values of a certain occupancy model is an average of the differences between the power consumption values corresponding to the combinations of that occupancy model and the respective pieces of past simulation target information and the actual power consumption value corresponding to that past simulation target information. The error calculation unit 106 calculates the error with respect to the actual power consumption value for each of the multiple occupancy models, based on the power consumption value corresponding to each combination of multiple past input conditions and the multiple occupancy models.

***Description of Operation***

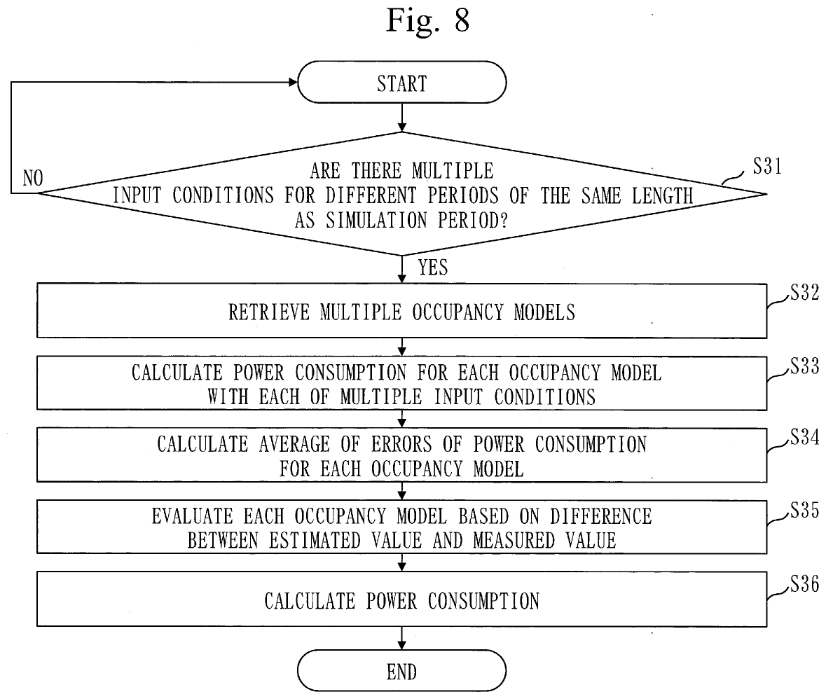

FIG. 8 is a flowchart illustrating an example of the operation of the occupancy model selection apparatus 100 according to Embodiment 3. With reference to this drawing, the operation of the occupancy model selection apparatus 100 is described.

(Step S31)

This step is similar to step S11. However, the input condition extraction unit 101 uses multiple pieces of past simulation target information in this step.

If there are multiple input conditions that correspond to periods equivalent to the simulation period of the same length as the simulation period, the occupancy model selection apparatus 100 moves on to step S32.

Otherwise, the occupancy model selection apparatus 100 repeats the processing for this step. In this case, the occupancy model selection apparatus 100 may also execute processing according to other embodiments.

(Step S32)

This step is the same as step S12.

(Step S33)

The occupancy model evaluation unit 102 calculates each power consumption value by executing a simulation for occupancy model selection using each of multiple pieces of past simulation target information output from the input condition extraction unit 101 and each occupancy model output from the occupancy model storage unit 182, and outputs the calculated power consumption values to the error calculation unit 106.

(Step S34)

The error calculation unit 106 calculates an average of the errors of the power consumption value for each occupancy model from the errors of the power consumption value of each occupancy model for the respective pieces of past simulation target information output from the occupancy model evaluation unit 102, the errors being with respect to the actual power consumption value of the facility corresponding to the past simulation target information output from the power consumption record storage unit 183, and outputs the calculated average of the errors to the occupancy model selection unit 103.

(Step S35)

The occupancy model selection unit 103 outputs, to the power consumption calculation unit 104, the occupancy model corresponding to the average of the smallest value among the averages of the errors of the power consumption value for the respective occupancy models output from the error calculation unit 106.

(Step S36)

This step is the same as step S15.

***Description of Effects of Embodiment 3***

Through the operations above, the occupancy model selection apparatus 100 according to Embodiment 3 can select an occupancy model having high simulation accuracy by selecting an occupancy model based on the result of a simulation using multiple pieces of past simulation target information. Thus, according to the present embodiment, definition of occupancy models is made more efficient by eliminating reconstruction of an occupancy model at the time of a simulation and the simulation accuracy of power consumption can be improved.

### Embodiment 4

In the following, differences from the aforementioned embodiment are chiefly described with reference to drawings.

In Embodiment 1, information on the simulation target area is used in a simulation for occupancy model selection.

In Embodiment 4, by contrast, information on a building or the like that is similar to the simulation target area is used. In the present embodiment, an area equivalent to the simulation target area includes an area similar to the simulation target area. Similarity of areas may be defined in any manner.

***Description of Configuration***

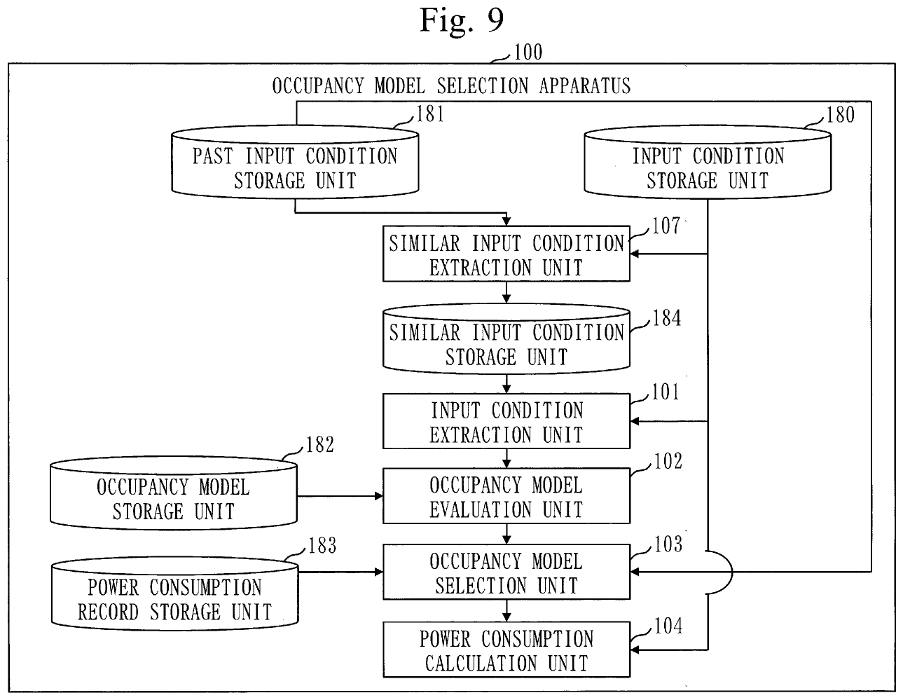

FIG. 9 shows an exemplary functional configuration of the occupancy model selection apparatus 100 according to the present embodiment. The occupancy model selection apparatus 100 is configured of the input condition storage unit 180, the past input condition storage unit 181, a similar input condition extraction unit 107, a similar input condition storage unit 184, the input condition extraction unit 101, the occupancy model storage unit 182, the occupancy model evaluation unit 102, the power consumption record storage unit 183, the occupancy model selection unit 103, and the power consumption calculation unit 104, as shown in FIG. 9. The similar input condition extraction unit 107 is also called a similar area past input condition extraction unit. The similar input condition storage unit 184 is also called a similar area past input condition storage unit.

The past input condition storage unit 181 also accumulates simulation target information that was input in a past simulation after occupancy model selection for an area other than the simulation target area as past simulation target information, and outputs accumulated past simulation target information.

(Similar Input Condition Extraction Unit 107)

The similar input condition extraction unit 107 retrieves one or more pieces of similar simulation target information, which is past simulation target information similar to the simulation target information output from the input condition storage unit 180, among pieces of past simulation target information output from the past input condition storage unit 181, and outputs the retrieved similar simulation target information. Similar simulation target information is past simulation target information that indicates conditions similar to the conditions indicated by the simulation target information. The conditions indicated by the simulation target information can be conditions related to the size of an area and the level of the area, as specific examples.

(Similar Input Condition Storage Unit 184)

The similar input condition storage unit 184 accumulates the one or more pieces of similar simulation target information output from the similar input condition extraction unit 107 and outputs accumulated similar simulation target information.

The occupancy model evaluation unit 102 uses the similar simulation target information instead of past simulation target information.

***Description of Operation***

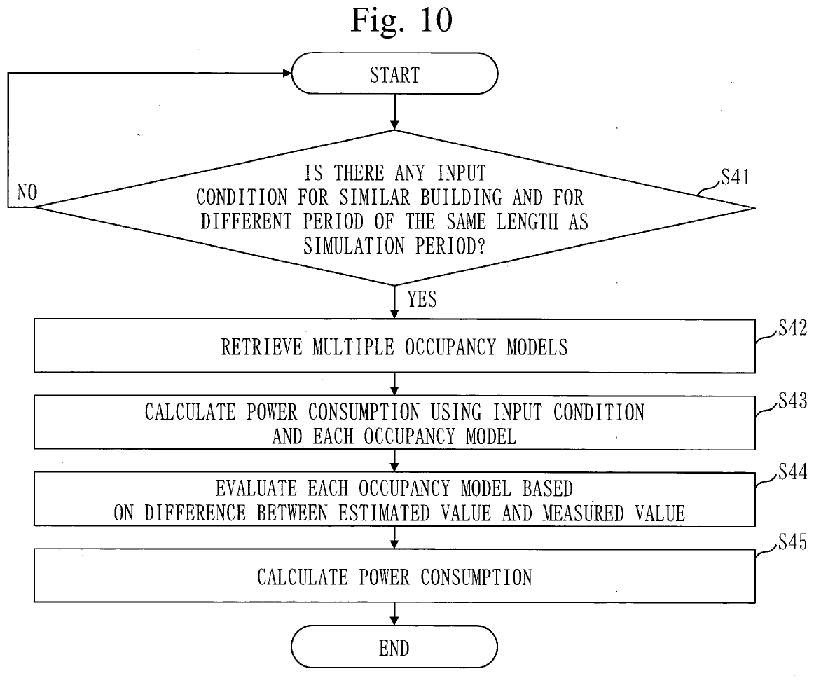

FIG. 10 is a flowchart illustrating an example of the operation of the occupancy model selection apparatus 100 according to the present embodiment. With reference to this drawing, the operation of the occupancy model selection apparatus 100 is described.

(Step S41)

The similar input condition extraction unit 107 retrieves one or more pieces of similar simulation target information for the simulation target information output from the input condition storage unit 180 among the pieces of past simulation target information output from the past input condition storage unit 181, and outputs the retrieved similar simulation target information to the similar input condition storage unit 184.

If there is no similar simulation target information, the occupancy model selection apparatus 100 repeats the processing for this step. In this case, the occupancy model selection apparatus 100 may also execute processing according to other embodiments.

The similar input condition extraction unit 107 calculates the length of the simulation period corresponding to the simulation target information output from the input condition storage unit 180, retrieves similar simulation target information corresponding to a period equivalent to the simulation period of the same length as the calculated length of the simulation period from the similar input condition storage unit 184, and outputs the retrieved similar simulation target information to the occupancy model evaluation unit 102.

(Step S42)

This step is the same as step S12.

(Step S43)

This step is similar to step S13. However, the occupancy model evaluation unit 102 uses the similar simulation target information output from the similar input condition extraction unit 107 instead of past simulation target information output from the input condition extraction unit 101.

(Step S44)

This step is the same as step S14.

(Step S45)

This step is the same as step S15.

***Description of Effects of Embodiment 4***

Through the operations above, the occupancy model selection apparatus 100 according to Embodiment 4 can select an occupancy model with a simulation for occupancy model selection by making use of past simulation records for a similar area even when there is no past simulation target information corresponding to the simulation target area.

### Embodiment 5

In the following, differences from the aforementioned embodiment are chiefly described with reference to drawings.

***Description of Configuration***

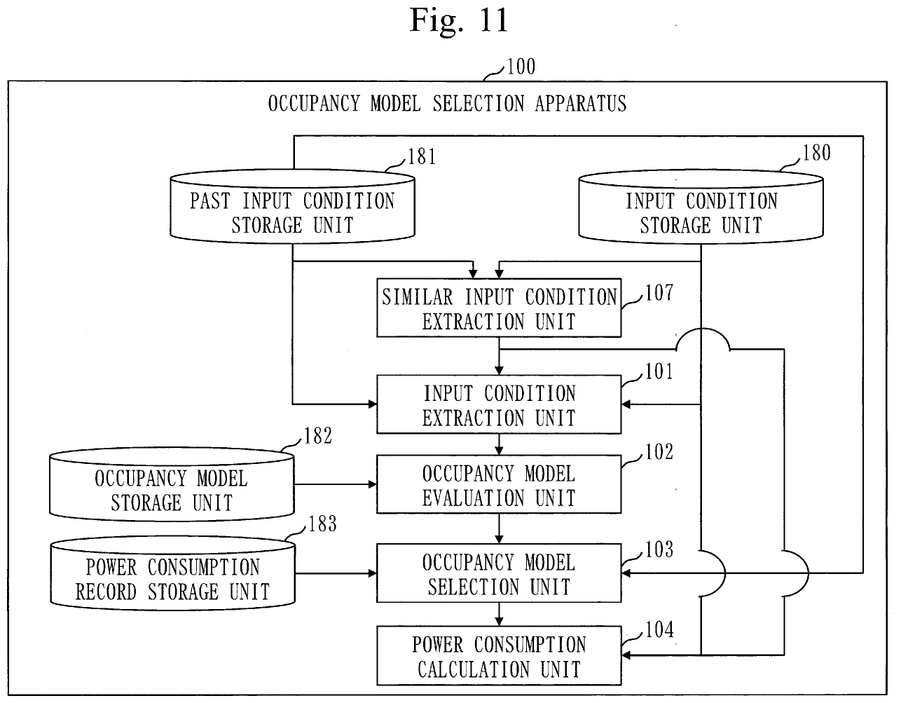

FIG. 11 shows an exemplary functional configuration of the occupancy model selection apparatus 100 according to the present embodiment. The occupancy model selection apparatus 100 is configured of the input condition storage unit 180, the past input condition storage unit 181, the similar input condition extraction unit 107, the input condition extraction unit 101, the occupancy model storage unit 182, the occupancy model evaluation unit 102, the power consumption record storage unit 183, the occupancy model selection unit 103, and the power consumption calculation unit 104, as shown in FIG. 11.

In the present embodiment, past input conditions include similar input conditions, which are conditions similar to the input condition.

(Similar Input Condition Extraction Unit 107)

When there is similar simulation target information which is similar to the simulation target information output from the input condition storage unit 180 among pieces of past simulation target information output from the past input condition storage unit 181, the similar input condition extraction unit 107 retrieves the occupancy model indicated by the similar simulation target information and outputs the retrieved occupancy model. Similar simulation target information is similar to that according to Embodiment 4. However, conditions such as the simulation target period, the size of the area, the level of the area, and the use of the area may be similar between past simulation target information output from the past input condition storage unit 181 and similar simulation target information.

The occupancy model selection unit 103 may also select the occupancy model indicated by a similar input condition as a selected occupancy model.

***Description of Operation***

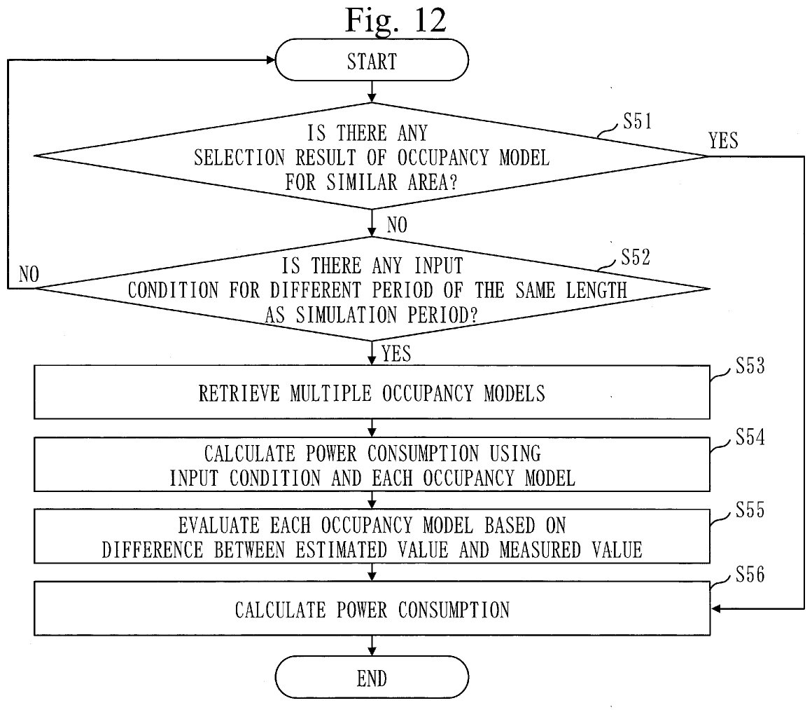

FIG. 12 is a flowchart illustrating an example of the operation of the occupancy model selection apparatus 100 according to Embodiment 5. With reference to this drawing, the operation of the occupancy model selection apparatus 100 is described.

(Step S51)

When there is similar simulation target information for the simulation target information output from the input condition storage unit 180 among the pieces of past simulation target information output from the past input condition storage unit 181, the similar input condition extraction unit 107 retrieves the occupancy model indicated by the similar simulation target information and outputs the retrieved occupancy model to the power consumption calculation unit 104. In this case, the occupancy model selection apparatus 100 moves on to step S56. In this case, the occupancy model retrieved by the similar input condition extraction unit 107 may be considered as selected by the occupancy model selection unit 103. Otherwise, the occupancy model selection apparatus 100 moves on to step S52.

(Step S52)

This step is the same as step S11.

(Step S53)

This step is the same as step S12.

(Step S54)

This step is the same as step S13.

(Step S55)

This step is the same as step S14.

(Step S56)

The power consumption calculation unit 104 calculates the power consumption value in the simulation target area during the simulation period by executing a simulation after occupancy model selection using the simulation target information output from the input condition storage unit 180 and the occupancy model output from the occupancy model selection unit 103 or from the similar input condition extraction unit 107.

***Description of Effects of Embodiment 5***

Through the operations above, the occupancy model selection apparatus 100 according to Embodiment 5 can speed up the selection of an occupancy model by exploiting an occupancy model that was selected for an area similar to the simulation target area in the past.

### Embodiment 6

In the following, differences from the aforementioned embodiment are chiefly described with reference to drawings.

***Description of Configuration***

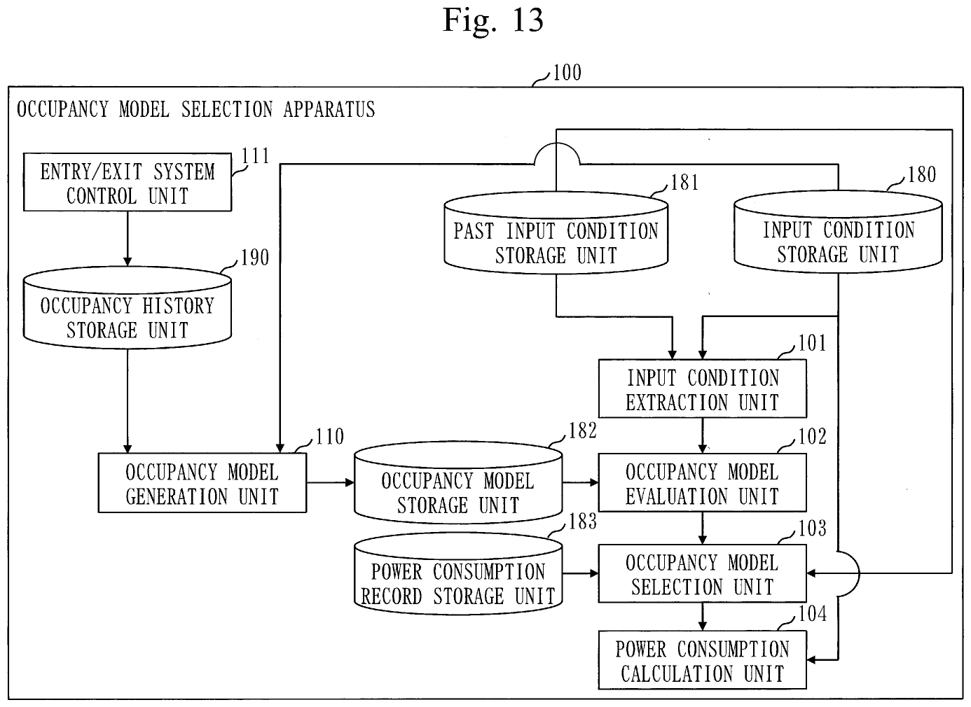

FIG. 13 shows an exemplary functional configuration of the occupancy model selection apparatus 100 according to the present embodiment. The occupancy model selection apparatus 100 is configured of the input condition storage unit 180, the past input condition storage unit 181, the input condition extraction unit 101, an entry/exit system control unit 111, an occupancy history storage unit 190, an occupancy model generation unit 110, the occupancy model storage unit 182, the occupancy model evaluation unit 102, the power consumption record storage unit 183, the occupancy model selection unit 103, and the power consumption calculation unit 104, as shown in FIG. 13.

(Entry/Exit System Control Unit 111)

The entry/exit system control unit 111 manages information showing each of entry and exit of people to/from the simulation target area, and outputs the number of occupants in the simulation target area for each time as needed based on the information being managed. For each time means for each time of day that satisfies predetermined conditions or for each hour of day, as specific examples. The entry/exit system control unit 111 manages entry/exit information showing people who enter and exit the simulation target area.

(Occupancy History Storage Unit 190)

The occupancy history storage unit 190 obtains information showing the number of occupants in the simulation target area for each time from the entry/exit system control unit 111, and accumulates the obtained information as an occupancy history. The occupancy history storage unit 190 stores occupancy histories, which are histories in the simulation target area and based on entry/exit information.

(Occupancy Model Generation Unit 110)

The occupancy model generation unit 110 calculates the length of the simulation period corresponding to the simulation target information output from the input condition storage unit 180, defines one or more occupancy models corresponding to a period(s) of the same length as the calculated length of the simulation period, and accumulates the defined occupancy model(s) in the occupancy model storage unit 182. The occupancy model generation unit 110 defines an occupancy model by correcting a past occupancy history for the simulation target area output from the occupancy history storage unit 190. The occupancy model generation unit 110 generates a generated occupancy model, which is an occupancy model for the simulation target area and which corresponds to the simulation period, based on entry/exit information.

The multiple occupancy models stored in the occupancy model storage unit 182 include generated occupancy models.

***Description of Operation***

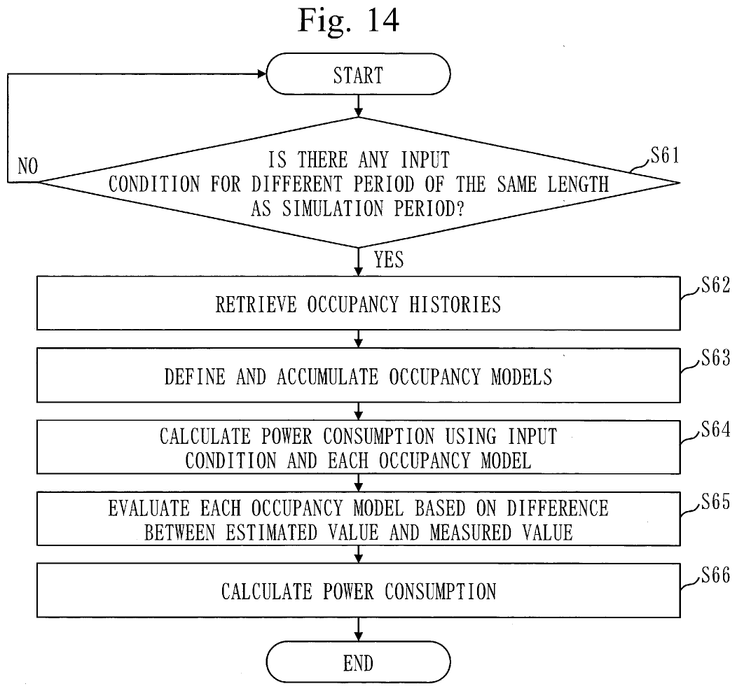

FIG. 14 is a flowchart illustrating an example of the operation of the occupancy model selection apparatus 100 according to Embodiment 6. With reference to this drawing, the operation of the occupancy model selection apparatus 100 is described.

(Step S61)

This step is the same as step S11.

(Step S62)

The occupancy model generation unit 110 retrieves an occupancy history corresponding to a period of the same length as the length of the simulation period from the occupancy history storage unit 190.

(Step S63)

The occupancy model generation unit 110 defines an occupancy model based on the retrieved occupancy history and accumulates the defined occupancy model in the occupancy model storage unit 182. As a specific example, the occupancy model generation unit 110 defines an occupancy model by converting numerical values indicated by the occupancy history into occupancy rates based on a normal number of occupants in the simulation target area retrieved from the input condition storage unit 180.

(Step S64)

This step is the same as step S13.

(Step S65)

This step is the same as step S14.

(Step S66)

This step is the same as step S15.

**Description of Effects of Embodiment 6***

Through the operations above, the occupancy model selection apparatus 100 according to Embodiment 6 uses occupancy histories for the simulation target area when defining multiple occupancy models, that is, it considers the actual number of occupants in the simulation target area. Thus, according to the present embodiment, the accuracy of a defined occupancy model is increased, which in turn can improve the accuracy of power consumption simulation.

### Embodiment 7

In the following, differences from the aforementioned embodiment are chiefly described with reference to drawings.

***Description of Configuration***

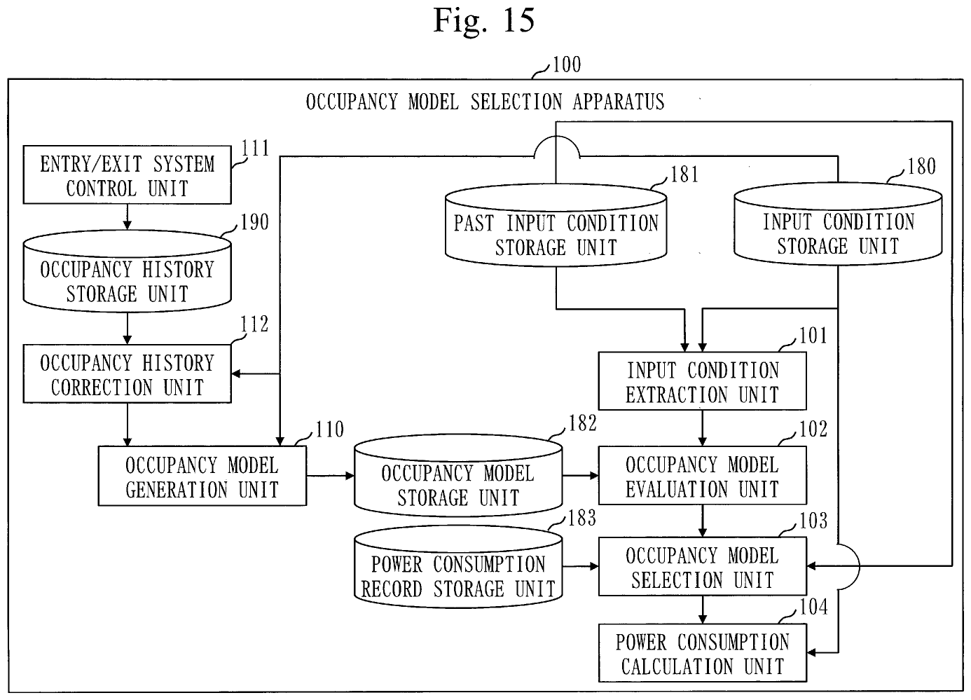

FIG. 15 shows an exemplary functional configuration of the occupancy model selection apparatus 100 according to the present embodiment. The occupancy model selection apparatus 100 is configured of the input condition storage unit 180, the past input condition storage unit 181, the input condition extraction unit 101, the entry/exit system control unit 111, the occupancy history storage unit 190, an occupancy history correction unit 112, the occupancy model generation unit 110, the occupancy model storage unit 182, the occupancy model evaluation unit 102, the power consumption record storage unit 183, the occupancy model selection unit 103, and the power consumption calculation unit 104, as shown in FIG. 15.

(Occupancy History Correction Unit 112)

When entry/exit information is not information for a period equivalent to the simulation period, the occupancy history correction unit 112 corrects the entry/exit information to generate within-period entry/exit information, which is information for a period equivalent to the simulation period. As a specific example, the occupancy history correction unit 112 retrieves occupancy histories over a certain period from the occupancy history storage unit 190, classifies the retrieved occupancy histories according to attributes, such as week day, holiday, or day of week, makes a correction such as averaging the occupancy histories belonging to each classification per classification, and outputs the corrected occupancy histories of the respective attributes.

The occupancy model generation unit 110 uses the within-period entry/exit information as entry/exit information.

***Description of Operation***

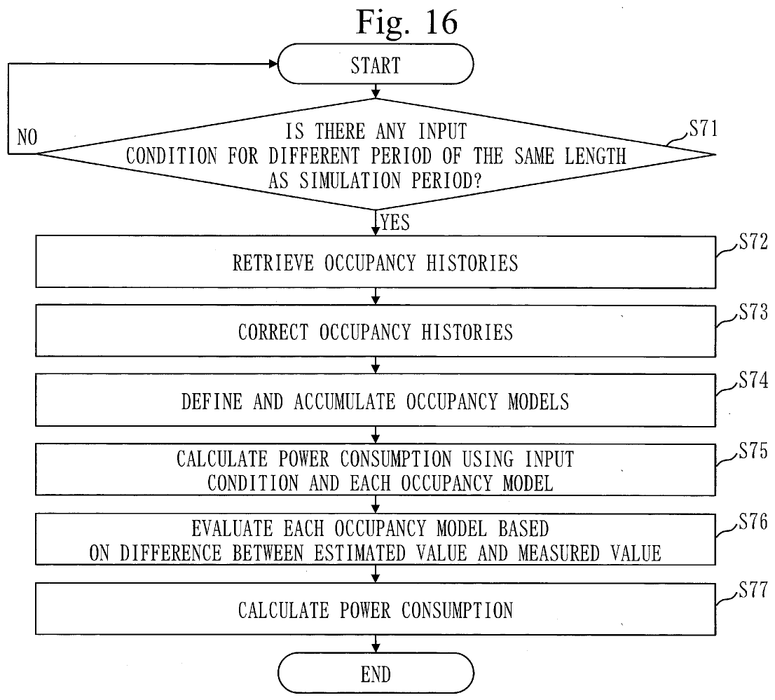

FIG. 16 is a flowchart illustrating an example of the operation of the occupancy model selection apparatus 100 according to Embodiment 7. With reference to this drawing, the operation of the occupancy model selection apparatus 100 is described.

(Step S71)

This step is the same as step S11.

(Step S72)

This step is similar to step S62. However, instead of the occupancy model generation unit 110, the occupancy history correction unit 112 retrieves occupancy histories.

(Step S73)

The occupancy history correction unit 112 classifies the occupancy histories retrieved from the occupancy history storage unit 190 according to attributes, corrects the occupancy histories belonging to each classification per classification, and outputs the corrected occupancy histories of the respective attributes to the occupancy model generation unit 110.

(Step S74)

The occupancy model generation unit 110 uses the occupancy histories of the respective attributes output from the occupancy history correction unit 112 to define an occupancy model for a period of the same length as the length of the simulation period, and accumulates the defined occupancy model in the occupancy model storage unit 182. As a specific example, the occupancy model generation unit 110 defines an occupancy model by converting the numerical values indicated by the occupancy histories of each attribute output from the occupancy history correction unit 112 into occupancy rates based on the normal number of occupants in the simulation target area retrieved from the input condition storage unit 180, and appropriately concatenating the converted occupancy rates into an occupancy model corresponding to a period of the same length as the simulation period.

As a specific example, an instance is described where the occupancy history correction unit 112 has classified occupancy histories over a certain period in the past retrieved from the occupancy history storage unit 190 according to day of week and has output the occupancy history for each day of week determined by averaging per day of week. In this case, the occupancy model generation unit 110 assigns the output occupancy history for each day of week to each day of week in the simulation period. As a specific example, if the simulation period is from Saturday, Jul. 10, 2021 to Wednesday, July 14, the occupancy model generation unit 110 assigns the occupancy history for Saturday to Saturday, July 10, the occupancy history for Sunday to Sunday, July 11, the occupancy history for Monday to Monday, July 12, the occupancy history for Tuesday to Tuesday, July 13, and the occupancy history for Wednesday to Wednesday, July 14.

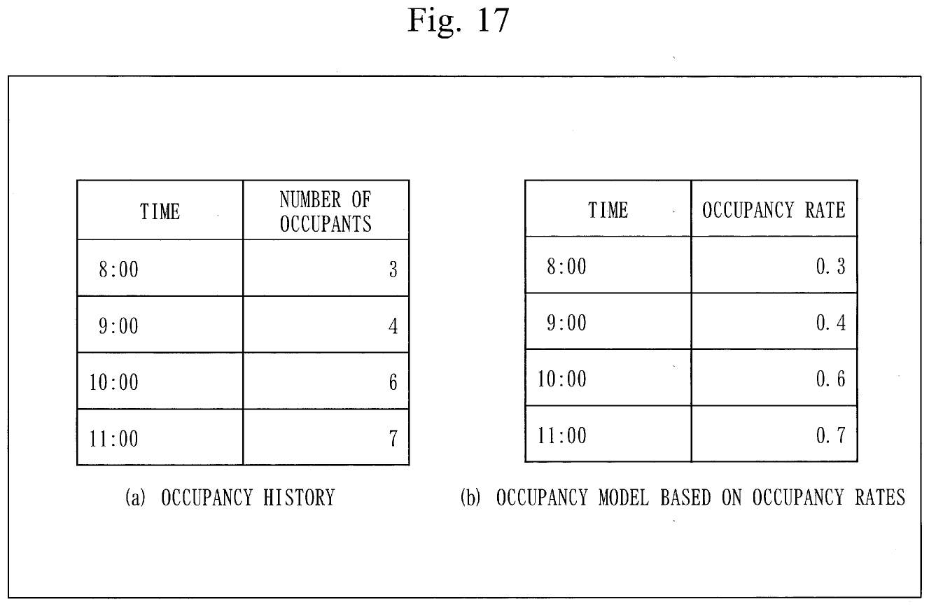

Referring to FIG. 17, an occupancy model based on occupancy rates is described. (a) of FIG. 17 shows an occupancy history on a certain day in a certain room, and (b) of FIG. 17 shows an occupancy model corresponding to (a) of FIG. 17 and based on occupancy rates. Here, the normal number of occupants in the room is assumed to be 10.

(Step S75)

This step is the same as step S13.

(Step S76) This step is the same as step S14.

(Step S77)

This step is the same as step S15.

***Description of Effects of Embodiment 7***

Through the operations above, the occupancy model selection apparatus 100 according to Embodiment 7 can define an occupancy model corresponding to a period of the same length as the length of the simulation period by utilizing occupancy histories of the respective attributes even when there is no occupancy history that corresponds to a period of the same length as the length of the simulation period.

### Embodiment 8

In the following, differences from the aforementioned embodiment are chiefly described with reference to drawings.

***Description of Configuration***

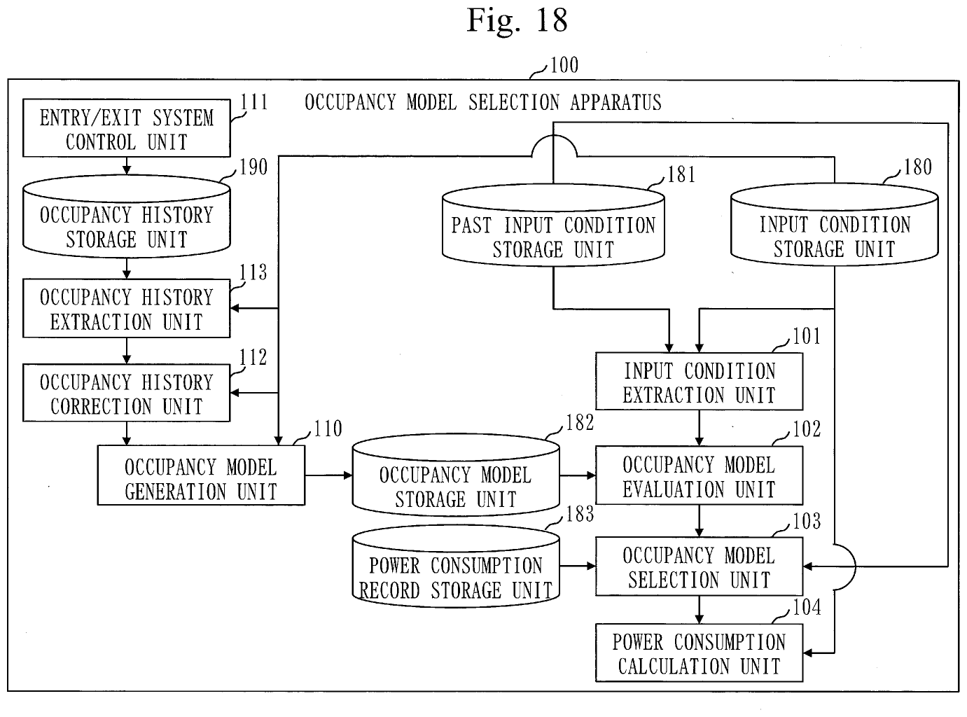

FIG. 18 shows an exemplary functional configuration of the occupancy model selection apparatus 100 according to the present embodiment. The occupancy model selection apparatus 100 is configured of the input condition storage unit 180, the past input condition storage unit 181, the input condition extraction unit 101, the entry/exit system control unit 111, the occupancy history storage unit 190, an occupancy history extraction unit 113, the occupancy history correction unit 112, the occupancy model generation unit 110, the occupancy model storage unit 182, the occupancy model evaluation unit 102, the power consumption record storage unit 183, the occupancy model selection unit 103, and the power consumption calculation unit 104, as shown in FIG. 18.

(Occupancy History Extraction Unit 113)

The occupancy history extraction unit 113 retrieves occupancy histories over a certain period from the occupancy history storage unit 190, excludes outliers in the number of occupants for each time from the retrieved occupancy histories, and outputs the occupancy histories from which outliers have been excluded. The occupancy history extraction unit 113 extracts occupancy histories, with outliers excluded, from the occupancy histories stored in the occupancy history storage unit 190.

The occupancy model generation unit 110 generates a generated occupancy model using the occupancy histories extracted by the occupancy history extraction unit 113.

***Description of Operation***

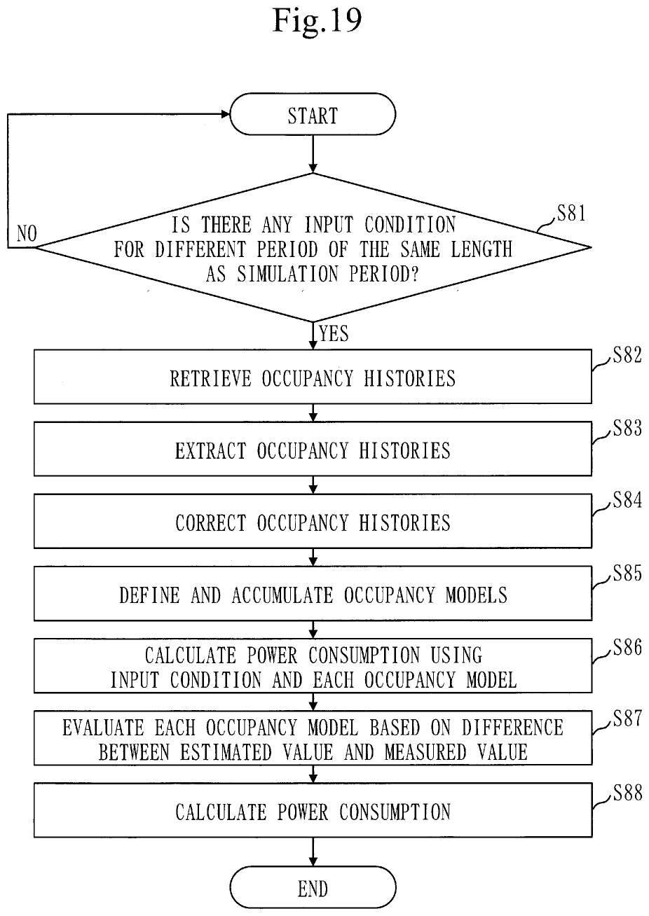

FIG. 19 is a flowchart illustrating an example of the operation of the occupancy model selection apparatus 100 according to Embodiment 8. With reference to this drawing, the operation of the occupancy model selection apparatus 100 is described.

(Step S81)

This step is the same as step S11.

(Step S82) This step is similar to step S62. However, instead of the occupancy model generation unit 110, the occupancy history extraction unit 113 retrieves occupancy histories.

(Step S83)

The occupancy history extraction unit 113 retrieves occupancy histories over a certain period from the occupancy history storage unit 190, excludes outliers in the number of occupants for each time from the retrieved occupancy histories, and outputs the occupancy histories from which outliers have been excluded to the occupancy history correction unit 112. As a specific example, the occupancy history extraction unit 113 excludes top and bottom 5% for each time from the retrieved occupancy histories as outliers in the number of occupants.

(Step S84)

This step is similar to step S73.

(Step S85)

This step is the same as step S74.

(Step S86)

This step is the same as step S13.

(Step S87)

This step is the same as step S14.

(Step S88) This step is the same as step S15.

***Description of Effects of Embodiment 8***

Through the operations above, the occupancy model selection apparatus 100 according to Embodiment 8 can define more accurate occupancy models by excluding outliers from occupancy histories.

### Embodiment 9

In the following, differences from the aforementioned embodiment are chiefly described with reference to drawings.

***Description of Configuration***

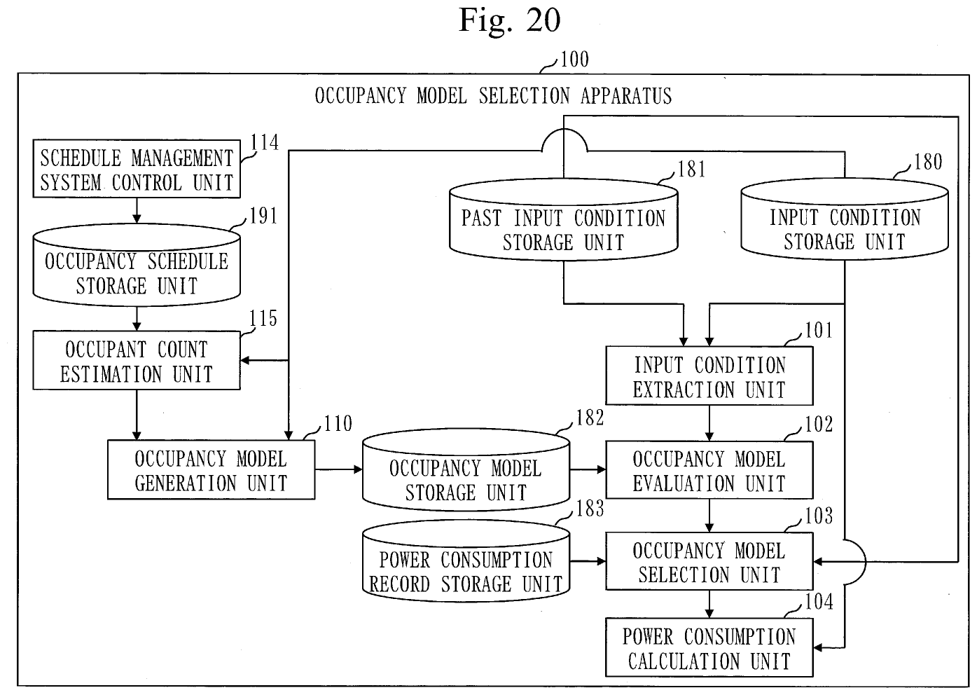

FIG. 20 shows an exemplary functional configuration of the occupancy model selection apparatus 100 according to the present embodiment. The occupancy model selection apparatus 100 is configured of the input condition storage unit 180, the past input condition storage unit 181, the input condition extraction unit 101, a schedule management system control unit 114, an occupancy schedule storage unit 191, an occupant count estimation unit 115, the occupancy model generation unit 110, the occupancy model storage unit 182, the occupancy model evaluation unit 102, the power consumption record storage unit 183, the occupancy model selection unit 103, and the power consumption calculation unit 104, as shown in FIG. 20.

(Schedule Management System Control Unit 114)

The schedule management system control unit 114 manages occupancy schedules which are entered by people who use the simulation target area via an input unit, not shown, aggregates the occupancy schedules of all the people who use the simulation target area for each time based on the occupancy schedules being managed, and outputs the aggregated occupancy schedule. The occupancy schedules managed by the schedule management system control unit 114 may also be entered via a separate system such as an attendance system. The schedule management system control unit 114 manages the occupancy schedule of each individual who stays in the simulation target area during the simulation period.

(Occupancy Schedule Storage Unit 191)

The occupancy schedule storage unit 191 accumulates occupancy schedules which are output from the schedule management system control unit 114 and correspond to the simulation target area for each time.

(Occupant Count Estimation Unit 115)

The occupant count estimation unit 115 retrieves occupancy schedules for the same period as the simulation period from the occupancy schedule storage unit 191, calculates the number of occupants for each time in the simulation period based on the retrieved occupancy schedules, and outputs the calculated number of occupants. The occupant count estimation unit 115 estimates the number of people that would be present in the simulation target area during the simulation period based on the occupancy schedule of each individual.

The occupancy model generation unit 110 generates a generated occupancy model based on the estimated number of people.

***Description of Operation***

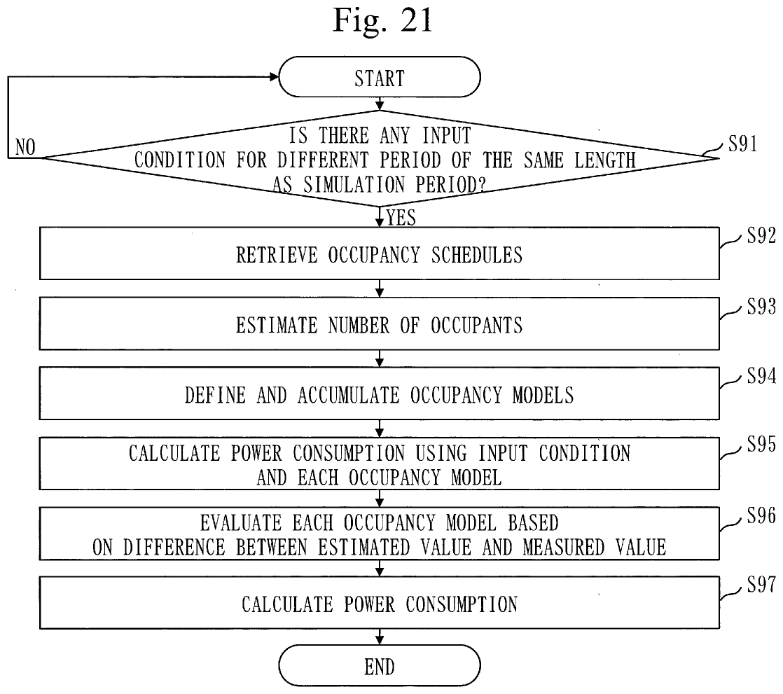

FIG. 21 is a flowchart illustrating an example of the operation of the occupancy model selection apparatus 100 according to Embodiment 9. With reference to this drawing, the operation of the occupancy model selection apparatus 100 is described.

(Step S91)

This step is the same as step S11.

(Step S92)

The schedule management system control unit 114 retrieves occupancy schedules for the same period as the simulation period, and outputs the retrieved occupancy schedules to the occupant count estimation unit 115 through the occupancy schedule storage unit 191.

(Step S93)

The occupant count estimation unit 115 calculates the number of occupants for each time in the simulation period based on the occupancy schedules retrieved from the occupancy schedule storage unit 191, and outputs the calculated number of occupants to the occupancy model generation unit 110.

(Step S94)

The occupancy model generation unit 110 defines an occupancy model based on the number of occupants for each time in the simulation period retrieved from the occupant count estimation unit 115 and accumulates the defined occupancy model in the occupancy model storage unit 182. As a specific example, the occupancy model generation unit 110 defines an occupancy model by converting the numerical values indicated by the occupancy history into occupancy rates based on the normal number of occupants in the simulation target area retrieved from the input condition storage unit 180.

(Step S95)

This step is the same as step S13.

(Step S96) This step is the same as step S14.

(Step S97)

This step is the same as step S15.

***Description of Effects of Embodiment 9***

Through the operations above, the occupancy model selection apparatus 100 according to Embodiment 9 uses occupancy schedules for the simulation target area when defining multiple occupancy models, that is, it considers the actual number of occupants in the simulation target area during the simulation period. Thus, according to the present embodiment, the accuracy of a defined occupancy model is increased, which in turn can improve the accuracy of power consumption simulation.

### Embodiment 10

In the following, differences from the aforementioned embodiment are chiefly described with reference to drawings.

***Description of Configuration***

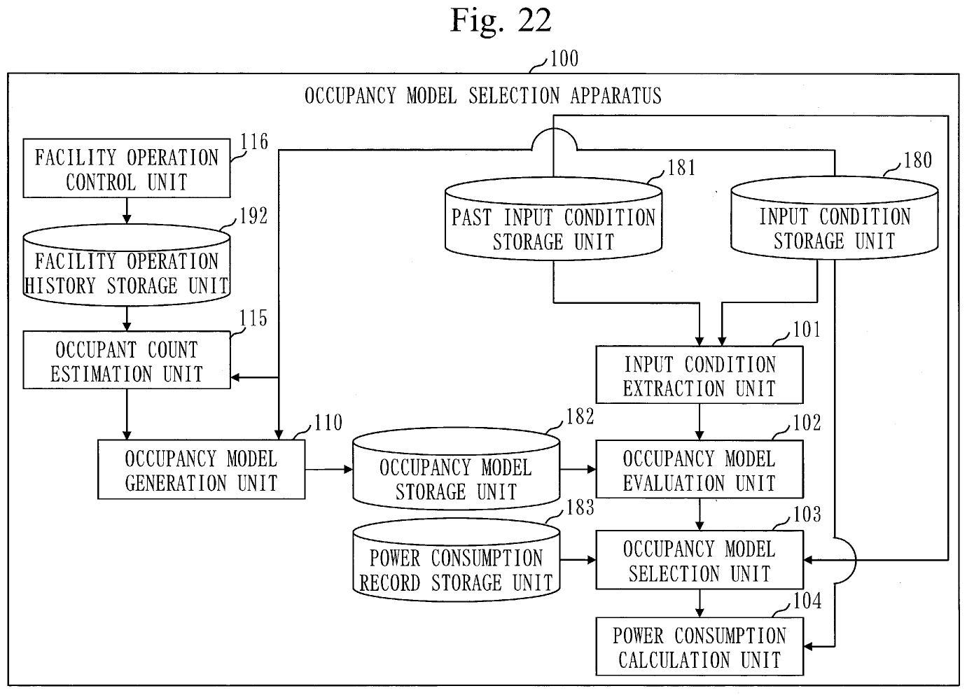

FIG. 22 shows an exemplary functional configuration of the occupancy model selection apparatus 100 according to the present embodiment. The occupancy model selection apparatus 100 is configured of the input condition storage unit 180, the past input condition storage unit 181, the input condition extraction unit 101, a facility operation control unit 116, a facility operation history storage unit 192, the occupant count estimation unit 115, the occupancy model generation unit 110, the occupancy model storage unit 182, the occupancy model evaluation unit 102, the power consumption record storage unit 183, the occupancy model selection unit 103, and the power consumption calculation unit 104, as shown in FIG. 22.

The occupant count estimation unit 115 retrieves information showing an operational situation of a facility in a period of the same length as the length of the simulation period from the facility operation history storage unit 192, calculates the number of occupants for each time in the simulation period based on the retrieved information, and outputs the calculated number of occupants. Information showing the operational situation of a facility is information that shows each of the operational status of the facility and the power consumption value of the facility for each time, as a specific example. The occupant count estimation unit 115 estimates the number of people that would be present in the simulation target area during the simulation period in accordance with the operational situation of the facility in the simulation target area.

The occupancy model generation unit 110 generates a generated occupancy model based on the estimated number of people.

(Facility Operation Control Unit 116)

The facility operation control unit 116 manages information showing the operational situation of the facility in the simulation target area, and outputs information being managed. The facility includes an air conditioner, a lighting device, and a ventilation device as specific examples. The facility operation control unit 116 manages information showing the operational situation of the facility in the simulation target area.

(Facility Operation History Storage Unit 192)

The facility operation history storage unit 192 accumulates information showing the operational situation of the facility for each time output from the facility operation control unit 116, and outputs accumulated information.

***Description of Operation***

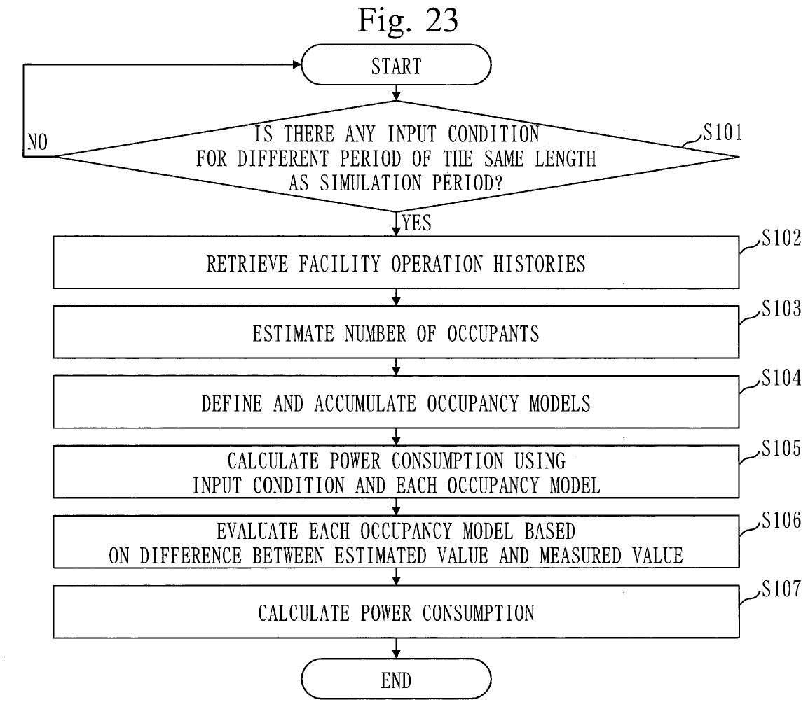

FIG. 23 is a flowchart illustrating an example of the operation of the occupancy model selection apparatus 100 according to Embodiment 10. With reference to this drawing, the operation of the occupancy model selection apparatus 100 is described.

(Step S101)

This step is the same as step S11.

(Step S102)

The facility operation control unit 116 retrieves information showing the operational situation of the facility in a period of the same length as the simulation period, and outputs the retrieved information to the occupant count estimation unit 115 through the facility operation history storage unit 192.

(Step S103)

The occupant count estimation unit 115 calculates an operation rate for each time in the simulation period based on the information showing the operational situation of the facility retrieved from the facility operation history storage unit 192, calculates the number of occupants for each time in the simulation period based on the calculated operation rate, and outputs the calculated number of occupants to the occupancy model generation unit 110. As a specific example, the occupant count estimation unit 115 calculates the number of occupants by calculating the operation rate with respect to a maximum power consumption value of the facility in the simulation target area based on the operational status and power consumption value of the facility, and applying the calculated operation rate to an occupancy rate with respect to the normal number of occupants in the simulation target area retrieved from the input condition storage unit 180 as the maximum, the occupancy rate corresponding to occupancy histories.

(Step S104)

This step is the same as step S94.

(Step S105)

This step is the same as step S13.

(Step S106) This step is the same as step S14.

(Step S107)

This step is the same as step S15.

***Description of Effects of Embodiment 10***

Through the operations above, the occupancy model selection apparatus 100 according to Embodiment 10 can calculate the number of occupants by considering the operational situation of a facility in the simulation target area when defining multiple occupancy models, even in cases where occupancy histories as used in Embodiment 6 or occupancy schedules as used in Embodiment 9 are not available.

### Embodiment 11

In the following, differences from the aforementioned embodiment are chiefly described with reference to drawings.

***Description of Configuration***

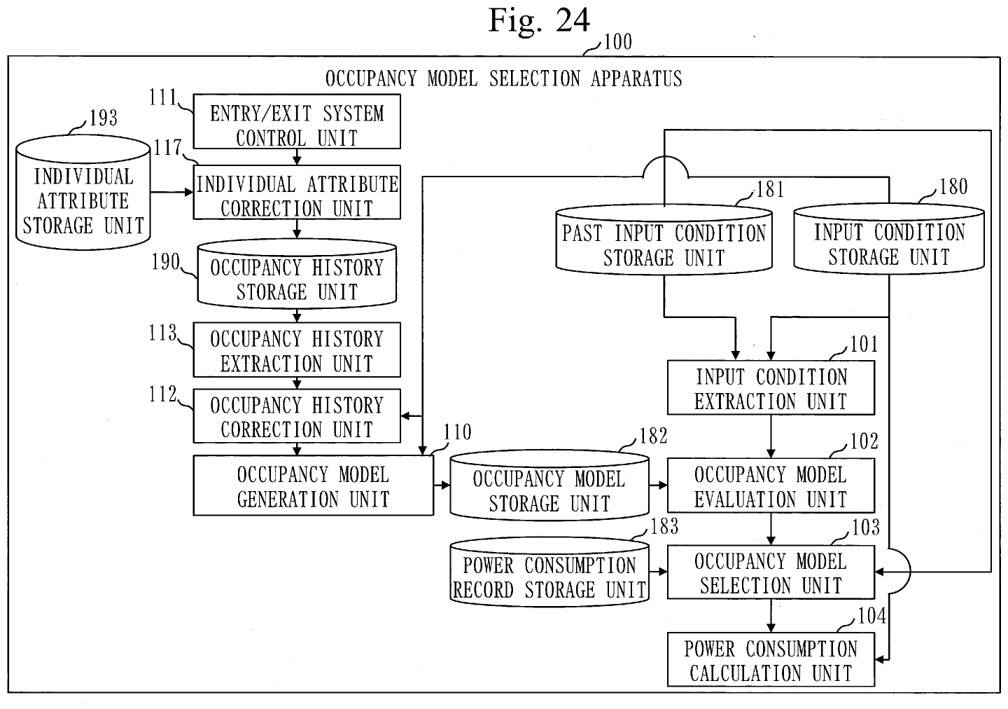

FIG. 24 shows an exemplary functional configuration of the occupancy model selection apparatus 100 according to the present embodiment. The occupancy model selection apparatus 100 is configured of the input condition storage unit 180, the past input condition storage unit 181, the input condition extraction unit 101, the entry/exit system control unit 111, an individual attribute storage unit 193, an individual attribute correction unit 117, the occupancy history storage unit 190, the occupancy history extraction unit 113, the occupancy history correction unit 112, the occupancy model generation unit 110, the occupancy model storage unit 182, the occupancy model evaluation unit 102, the power consumption record storage unit 183, the occupancy model selection unit 103, and the power consumption calculation unit 104, as shown in FIG. 24.

The occupancy history storage unit 190 obtains the number of occupants in the simulation target area for each time from the individual attribute correction unit 117, accumulates the obtained number of occupants as an occupancy history, and outputs accumulated occupancy histories.

(Individual Attribute Storage Unit 193)

The individual attribute storage unit 193 accumulates information showing attributes of individuals and outputs accumulated information. The individual's attributes correspond to the gender, age, and build of the individual, as specific examples.

(Individual Attribute Correction Unit 117)

The individual attribute correction unit 117 estimates a calorific value of each individual based on the attribute of the individual output from the individual attribute storage unit 193, makes a correction to reflect the proportion of the estimated calorific value of the individual to the number of occupants for each time output from the entry/exit system control unit 111, and outputs the corrected number of occupants. In doing so, as a specific example, the individual attribute correction unit 117 estimates the proportion of the calorific value of each individual with respect to a normal calorific value of a single person in accordance with the individual's attributes which are output from the individual attribute storage unit 193, and corrects the number of occupants based on the estimated proportion. As a specific example, if the calorific value of a certain person is double the normal calorific value, the individual attribute correction unit 117 counts the person as two persons. The individual attribute correction unit 117 may also estimate the calorific value of each individual in accordance with his/her activity and the like.

The individual attribute correction unit 117 corrects entry/exit information to information that reflects the attributes of each individual present in the simulation target area. The individual attribute correction unit 117 may also correct entry/exit information to information that reflects a calorific value dependent on the attributes of each individual present in the simulation target area.

The occupancy model generation unit 110 generates a generated occupancy model using the corrected entry/exit information.

***Description of Operation***

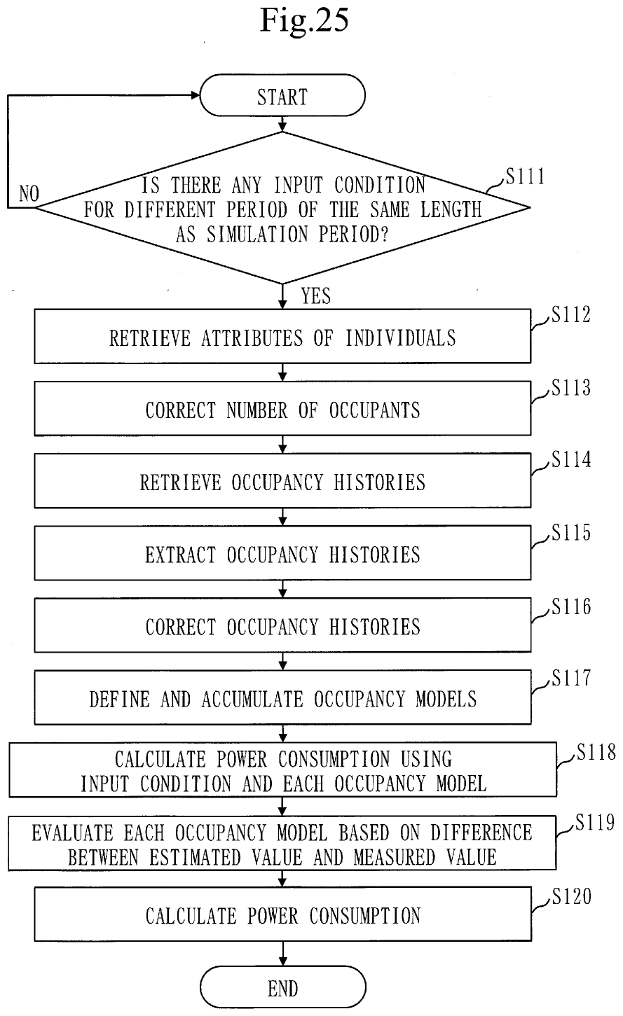

FIG. 25 is a flowchart illustrating an example of the operation of the occupancy model selection apparatus 100 according to Embodiment 11. With reference to this drawing, the operation of the occupancy model selection apparatus 100 is described.

(Step S111)

This step is the same as step S11.

(Step S112)

The individual attribute correction unit 117 retrieves the attributes of individuals from the individual attribute storage unit 193.

(Step S113)

The individual attribute correction unit 117 corrects the number of occupants for each time output from the entry/exit system control unit 111 on the basis of the attributes of individuals output from the individual attribute storage unit 193, and outputs the corrected number of occupants to the occupancy history storage unit 190.

(Step S114)

This step is the same as step S82.

(Step S115)

This step is the same as step S83.

(Step S116)

This step is the same as step S84.

(Step S117)

This step is the same as step S85.

(Step S118)

This step is the same as step S13.

(Step S119)

This step is the same as step S14.

(Step S120)

This step is the same as step S15.

***Description of Effects of Embodiment 11***

Through the operations above, the occupancy model selection apparatus 100 according to Embodiment 11 reflects, for example, calorific values dependent on the attributes of individuals in definition of occupancy models. Thus, according to the present embodiment, the accuracy of a defined occupancy model is increased, which in turn can improve the accuracy of power consumption simulation.

### Embodiment 12

In the following, differences from the aforementioned embodiment are chiefly described with reference to drawings.

***Description of Configuration***

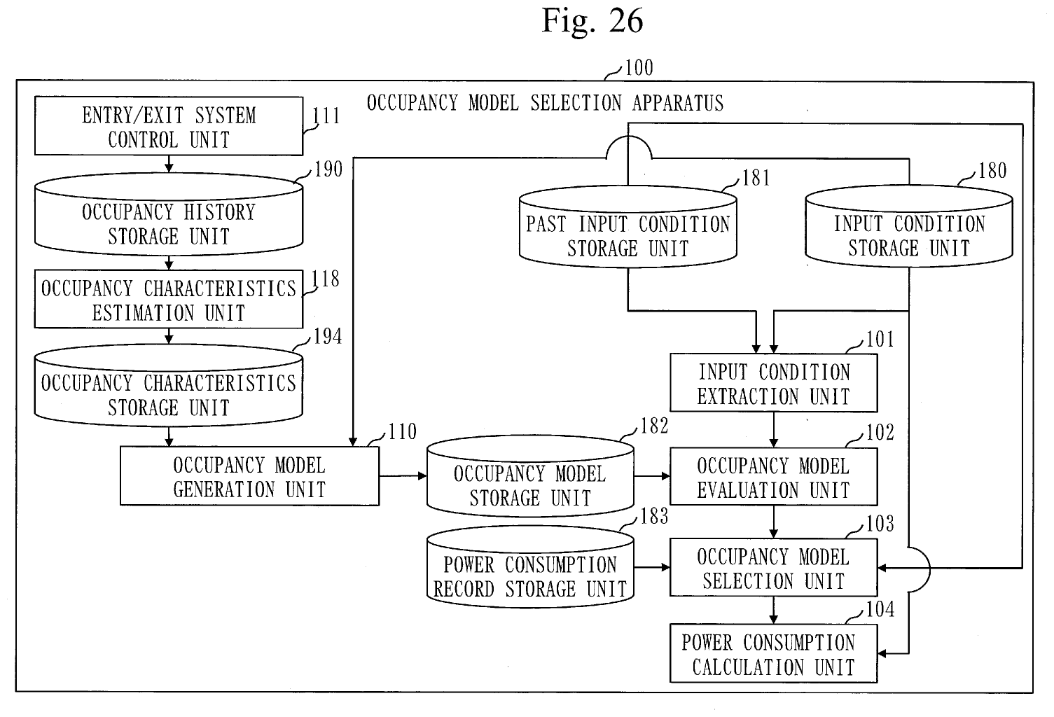

FIG. 26 shows an exemplary functional configuration of the occupancy model selection apparatus 100 according to the present embodiment. The occupancy model selection apparatus 100 is configured of the input condition storage unit 180, the past input condition storage unit 181, the input condition extraction unit 101, the entry/exit system control unit 111, the occupancy history storage unit 190, an occupancy characteristics estimation unit 118, an occupancy characteristics storage unit 194, the occupancy model generation unit 110, the occupancy model storage unit 182, the occupancy model evaluation unit 102, the power consumption record storage unit 183, the occupancy model selection unit 103, and the power consumption calculation unit 104, as shown in FIG. 26. The occupancy characteristics estimation unit 118 is also called an individual occupancy characteristics estimation unit. The occupancy characteristics storage unit 194 is also called an individual occupancy characteristics storage unit.

The occupancy model generation unit 110 aggregates the occupancy characteristics of individuals in the simulation target area output from the occupancy characteristics storage unit 194 and defines an occupancy model corresponding to a period of the length of the simulation period based on the aggregated occupancy characteristics.

(Occupancy Characteristics Estimation Unit 118)

The occupancy characteristics estimation unit 118 classifies occupancy histories output from the occupancy history storage unit 190 into each individual's occupancy history, defines the occupancy characteristics of each individual based on the classified occupancy history of the individual, and outputs information showing the defined occupancy characteristics of each individual. As a specific example, the occupancy characteristics estimation unit 118 identifies, for each individual, an area in which the individual stayed the longest among simulation target areas in the time range indicated by his/her occupancy history, and defines the occupancy characteristics of the individual based on the possibility that the individual will be present in the area identified for that individual and the possibility that the individual will not be present there in each hour of day. The occupancy characteristics estimation unit 118 estimates occupancy characteristics, which are characteristics related to occupancy of each individual present in the simulation target area, based on entry/exit information.

The occupancy model generation unit 110 generates a generated occupancy model based on the estimated occupancy characteristics.

(Occupancy Characteristics Storage Unit 194)

The occupancy characteristics storage unit 194 accumulates information showing each individual's occupancy characteristics output from the occupancy characteristics estimation unit 118 and outputs accumulated information.

***Description of Operation***

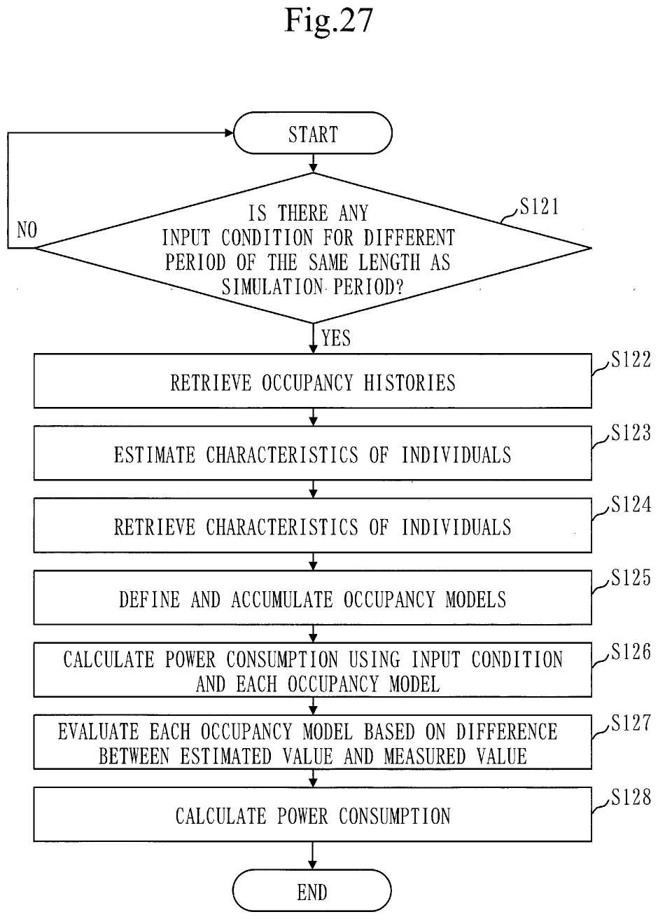

FIG. 27 is a flowchart illustrating an example of the operation of the occupancy model selection apparatus 100 according to Embodiment 12. With reference to this drawing, the operation of the occupancy model selection apparatus 100 is described.

(Step S121)

This step is the same as step S11.

(Step S122)

This step is similar to step S62. However, instead of the occupancy model generation unit 110, the occupancy characteristics estimation unit 118 retrieves occupancy histories.

(Step S123)

The occupancy characteristics estimation unit 118 classifies occupancy histories output from the occupancy history storage unit 190 into each individual's occupancy history, defines the occupancy characteristics of each individual based on the classified occupancy history of the individual, and outputs information showing the defined occupancy characteristics of each individual to the occupancy characteristics storage unit 194.

(Step S124)

The occupancy model generation unit 110 retrieves the occupancy characteristics of each individual who uses the simulation target area from the occupancy characteristics storage unit 194.

(Step S125)

The occupancy model generation unit 110 aggregates the number of occupants for each time in a period of the length of the simulation period based on the occupancy characteristics for the simulation target area retrieved from the occupancy characteristics storage unit 194, defines an occupancy model based on the aggregated number of occupants for each time, and accumulates the defined occupancy model in the occupancy model storage unit 182. In doing so, as a specific example, the occupancy model generation unit 110 defines an occupancy model corresponding to a period of the length of the simulation period by converting the aggregated number of occupants for each time into an occupancy rate on the basis of the normal number of occupants in the simulation target area retrieved from the input condition storage unit 180.

(Step S126)

This step is the same as step S13.

(Step S127)

This step is the same as step S14.

(Step S128)

This step is the same as step S15.

***Description of Effects of Embodiment 12***

Through the operations above, in a case where a significant change in the number of occupants in the simulation target area is expected such as due to moving in or out of a tenant and it is not desirable to apply occupancy histories as used in Embodiment 6 as a specific example, the occupancy model selection apparatus 100 according to Embodiment 12 still can define an appropriate occupancy model by using the occupancy characteristics of individuals who will be present after a relocation and select an appropriate occupancy model from the defined occupancy models.

### Other Embodiments

Any combination of the embodiments described above, modification to any component in the embodiments, or omission of any component in the embodiments is possible.

Also, embodiments are not limited to the ones shown as Embodiments 1 to 12 and various modifications are possible as needed. Procedures described with flowcharts or the like may be modified as appropriate.

### REFERENCE SIGNS LIST

11: processor; 12: main storage device; 13: auxiliary storage device; 14: input interface; 15: output interface; 16: communication interface; 18: processing circuit; 100: occupancy model selection apparatus; 101: input condition extraction unit; 102: occupancy model evaluation unit; 103: occupancy model selection unit; 104: power consumption calculation unit; 105: input condition evaluation unit; 106: error calculation unit; 107: similar input condition extraction unit; 110: occupancy model generation unit; 111: entry/exit system control unit; 112: occupancy history correction unit; 113: occupancy history extraction unit; 114: schedule management system control unit; 115: occupant count estimation unit; 116: facility operation control unit; 117: individual attribute correction unit; 118: occupancy characteristics estimation unit; 180: input condition storage unit; 181: past input condition storage unit; 182: occupancy model storage unit; 183: power consumption record storage unit; 184: similar input condition storage unit; 190: occupancy history storage unit; 191: occupancy schedule storage unit; 192: facility operation history storage unit; 193: individual attribute storage unit; 194: occupancy characteristics storage unit.

1. An occupancy model selection apparatus comprising:
processing circuitry to evaluate each of a plurality of occupancy models which predict occupancy situation in a simulation target area during a simulation period, the evaluating based on a power consumption value corresponding to each of the plurality of occupancy models and on a past input condition, the past input condition being a condition that affects a power consumption value in an area equivalent to the simulation target area during a period equivalent to the simulation period and that was used in a past simulation of the power consumption value in an area equivalent to the simulation target area during a period equivalent to the simulation period; and based on a result of evaluation of each of the plurality of occupancy models, further selects as a selected occupancy model from among the plurality of occupancy models, an occupancy model that generates a simulation result relatively close to an actual power consumption value in the simulation period corresponding to the past input condition in the area equivalent to the simulation target area, in a simulation of power consumption in an area equivalent to the simulation target area during a period equivalent to the simulation period.

2. The occupancy model selection apparatus according to claim 1, wherein
the processing circuitry determines the power consumption value corresponding to each of the plurality of occupancy models based on each of the plurality of occupancy models and on the past input condition.

3. The occupancy model selection apparatus according to claim 2, wherein
for determining the power consumption value corresponding to each of the plurality of occupancy models, the processing circuitry obtains a plurality of simulation results corresponding to the plurality of occupancy models, respectively, by simulating the power consumption value in the area equivalent to the simulation target area during the period equivalent to the simulation period using each of the plurality of occupancy models and the past input condition, and
the processing circuitry selects an occupancy model corresponding to a simulation result that is relatively close to the actual power consumption value among the plurality of simulation results as the selected occupancy model.

4. The occupancy model selection apparatus according to claim 2, wherein
a plurality of the past input conditions are present,
for determining the power consumption value corresponding to each of the plurality of occupancy models, the processing circuitry determines a power consumption value corresponding to each combination of the plurality of past input conditions and the plurality of occupancy models by a simulation,
the processing circuitry calculates an error with respect to the actual power consumption value for each of the plurality of occupancy models, based on the power consumption value corresponding to each combination of the plurality of past input conditions and the plurality of occupancy models, and
the processing circuitry selects the selected occupancy model based on the error with respect to the actual power consumption value for each of the plurality of occupancy models.

5. The occupancy model selection apparatus according to claim 1, wherein
the processing circuitry stores each of one or more past input conditions in association with a simulation result of a simulation that uses each of the one or more past input conditions and that is for the power consumption value in the area equivalent to the simulation target area during the period equivalent to the simulation period,
the processing circuitry selects, as a similar-power occupancy model, an occupancy model that corresponds to a simulation result relatively close to the actual power consumption value from among occupancy models indicated by the one or more past input conditions, respectively, and
for evaluating each of the plurality of occupancy models, the processing circuitry evaluates a difference between each of the plurality of occupancy models and the similar-power occupancy model and selects an occupancy model with a relatively small difference with respect to the similar-power occupancy model as the selected occupancy model.

6. The occupancy model selection apparatus according to claim 1, wherein
the area equivalent to the simulation target area includes an area similar to the simulation target area.

7. The occupancy model selection apparatus according to claim 1, wherein
the past input condition includes a similar input condition, which is a condition similar to an input condition, the input condition being a condition that affects the power consumption value in the simulation target area during the simulation period, and
the processing circuitry selects an occupancy model indicated by the similar input condition as the selected occupancy model.

8. The occupancy model selection apparatus according to claim 1, wherein
the processing circuitry manages entry/exit information showing people who enter and exit the simulation target area,
the processing circuitry generates a generated occupancy model based on the entry/exit information, the generated occupancy model being an occupancy model for the simulation target area and corresponding to the simulation period, and
the plurality of occupancy models include the generated occupancy model.

9. The occupancy model selection apparatus according to claim 8, wherein
the processing circuitry, when the entry/exit information is not information for a period equivalent to the simulation period, corrects the entry/exit information to generate within-period entry/exit information, the within-period entry/exit information being information for the period equivalent to the simulation period, and
the processing circuitry uses the within-period entry/exit information as the entry/exit information.

10. The occupancy model selection apparatus according to claim 8, wherein
the processing circuitry stores occupancy histories, the occupancy histories being histories in the simulation target area and based on the entry/exit information,
the processing circuitry extracts occupancy history, with outliers excluded, from the occupancy histories stored, and
the processing circuitry generates the generated occupancy model using an extracted occupancy history.

11. The occupancy model selection apparatus according to claim 8, wherein
the processing circuitry manages an occupancy schedule of each individual who stays in the simulation target area during the simulation period,
the processing circuitry estimates the number of people that would be present in the simulation target area during the simulation period based on the occupancy schedule of each individual, and
the processing circuitry generates the generated occupancy model based on an estimated number of people.

12. The occupancy model selection apparatus according to claim 8, wherein
the processing circuitry manages information showing an operational situation of a facility in the simulation target area,
the processing circuitry estimates the number of people that would be present in the simulation target area during the simulation period in accordance with the operational situation of the facility in the simulation target area, and
the processing circuitry generates the generated occupancy model based on an estimated number of people.

13. The occupancy model selection apparatus according to claim 8, wherein
the processing circuitry corrects the entry/exit information to information that reflects attributes of each individual present in the simulation target area, and
the processing circuitry generates the generated occupancy model using corrected entry/exit information.

14. The occupancy model selection apparatus according to claim 13, wherein
the processing circuitry corrects the entry/exit information to information that reflects a calorific value dependent on the attributes of each individual present in the simulation target area.

15. The occupancy model selection apparatus according to claim 8, wherein
the processing circuitry estimates occupancy characteristics based on the entry/exit information, the occupancy characteristics being characteristics related to occupancy of each individual present in the simulation target area, and
the processing circuitry generates the generated occupancy model based on estimated occupancy characteristics.

16. An occupancy model selection method comprising:
evaluating, by a computer, each of a plurality of occupancy models which predict occupancy situation in a simulation target area during a simulation period, the evaluating based on a power consumption value corresponding to each of the plurality of occupancy models and on a past input condition, the past input condition being a condition that affects a power consumption value in an area equivalent to the simulation target area during a period equivalent to the simulation period and that was used in a past simulation of the power consumption value in an area equivalent to the simulation target area during a period equivalent to the simulation period; and based on a result of evaluation of each of the plurality of occupancy models, further selecting as a selected occupancy model from among the plurality of occupancy models, an occupancy model that generates a simulation result relatively close to an actual power consumption value in the simulation period corresponding to the past input condition in the area equivalent to the simulation target area, in a simulation of power consumption in an area equivalent to the simulation target area during a period equivalent to the simulation period.

17. A non-transitory computer readable medium storing an occupancy model selection program that causes an occupancy model selection apparatus as a computer to execute:
an occupancy model selection process to evaluate each of a plurality of occupancy models which predict occupancy situation in a simulation target area during a simulation period, the evaluating based on a power consumption value corresponding to each of the plurality of occupancy models and on a past input condition, the past input condition being a condition that affects a power consumption value in an area equivalent to the simulation target area during a period equivalent to the simulation period and that was used in a past simulation of the power consumption value in an area equivalent to the simulation target area during a period equivalent to the simulation period; and based on a result of evaluation of each of the plurality of occupancy models, further to select as a selected occupancy model from among the plurality of occupancy models, an occupancy model that generates a simulation result relatively close to an actual power consumption value in the simulation period corresponding to the past input condition in the area equivalent to the simulation target area, in a simulation of power consumption in an area equivalent to the simulation target area during a period equivalent to the simulation period.
